(19) United States
(12) Patent Application Publication
(10) Pub. No.: US 2007/0007241 A1
(43) Pub. Date: Jan. 11, 2007

(54) Methods of making and modifying porous devices for biomedical applications

(75) Inventor: Lisa DeLouise, Rochester, NY (US)

Correspondence Address: NIXON PEABODY LLP - PATENT GROUP, CLINTON SQUARE, P.O. BOX 31051, ROCHESTER, NY, 14603-1051, US

(73) Assignee: University of Rochester, Rochester, NY (US)

(21) Appl. No.: 11/407,988

(22) Filed: Apr. 20, 2006

Related U.S. Application Data
(60) Provisional application No. 60/673,108, filed on Apr. 20, 2005.

(51) Int. Cl. B31D 3/00; C09K 13/00; B44C 1/22; H01L 21/461

(52) U.S. Cl. 216/56; 252/79.1; 438/745; 216/83; 428/131

(57) ABSTRACT

Etchant solutions for making porous semiconductor materials. Also disclosed are methods of making porous semiconductor materials, post etch treatments, and porous semiconductor materials produced by these methods.

This application claims the benefit of U.S. Provisional Patent Application Ser. No. 60/673,108, filed Apr. 20, 2005, which is hereby incorporated by reference in its entirety.

### FIELD OF THE INVENTION

The present invention relates generally to etchant solutions and their use in making porous semiconductor materials, and porous semiconductor materials produced therewith.

### BACKGROUND OF THE INVENTION

Porous devices used in biomedical and bioanalytical assays (e.g., affinity biosensors, immobilized enzyme biocatalysts, drug delivery devices, and tissue engineering devices) that require infiltration of reagents must be designed to enable facile ingress and egress through the porous matrix. Such devices include porous silicon optical sensors (e.g., microcavities, Bragg mirrors, thin film interferometers, and Rugate filters) fabricated by anodic electrochemical dissolution of a single crystal wafer in an HF-containing electrolyte. The detection principle of these devices is based on measuring changes in refractive index caused by substances binding to receptors immobilized within the volume of the porous matrix. For biosensor applications, many target molecules of interest possess molecular weight exceeding 10 kDa. A typical immunoglobin like IgG has a molecular weight of 150 kDa and a diameter of ˜15 nm. Sandwich-type immunoanalytical assays require stacking of two or more IgG-type molecules. Hence, conducting such assays using a sensor where the detection signal is generated from interactions that occur within the volume of the device requires that the morphology be sufficient to accommodate these types of biomolecules.

Mesoporous silicon microcavity sensors fabricated from p+ silicon have been successfully utilized in detection assays for biomolecular reagents less than ˜30 kDa. Biomolecules exceeding this size require larger pore dimensions, which can be achieved through modification of mesoporous structure or by fabricating macroporous devices. Detection of 30-50 kDa proteins using a post-etch-modified p+ mesoporous microcavity has been successfully demonstrated (DeLouise & Miller, “Optimization of Mesoporous Silicon Microcavities for Proteomic Sensing,” Mat. Res. Soc. Symp. Proc. 782:A5.3.1 (2004); DeLouise & Miller, “Quantitative Assessment of Enzyme Immobilization Capacity in Porous Silicon,” Anal. Chem. 76(23):6915-6920 (2004)). Those experienced in the art know that a wide range of pore sizes and channel morphologies can be fabricated directly by changing electrochemical etch parameters including etchant formulation, doping level and type, and current density. However, systematic teaching on this topic does not exist despite the vast amount of published literature (Zhang, “Morphology and Formation Mechanisms of Porous Silicon,” Electrochem. Soc. 151(1):C69-C80 (2004); Lehman et al., Mater. Sci. Eng. B69:11 (2000)) on the subject. Consequently, it currently remains a significant challenge to consistently control the fabrication of reproducible structures with an understanding of the trade-offs associated with generating large pore diameters that enable facile biomolecular infiltration while minimizing interface roughness to yield the desired high quality optical device characteristics. Roughness characteristics resulting from large pore devices may be thought of as a distance between crests of a wave front. Peak-to-peak distances and the amplitude of the peak to valley are much larger for macropores than for mesopores and, hence, rougher on an optical scale, as illustrated in FIG. 1. It is desired to be able to control pore morphology (diameter and porosity) over a wide range, and, for biosensors, 50-100 nm diameter pores seem ideal.

The quality of biosensor devices designed around either type of porous microstructure and the extent to which equivalently functional devices can be reproducibly made depends critically on the electrochemical etch cell design and the process control of critical parameters such as current density, doping level, and etchant composition. Device sensitivity on the other hand is linked to various design parameters including device type (single layer, mirror, or microcavity) (Anderson et al., “Sensitivity of the Optical Properties of Porous Silicon Layers to the Refractive Index of Liquid in the Pores,” Phys. Stat. Sol. (a) 197(2):528-533 (2003)), detection mode (reflection or photoluminescence), spectral operating range (IR, Vis) (Canham et al., “Derivatized Porous Silicon Mirrors: Implantable Optical Components with Slow Resorbability,” Phys. Stat. Sol. (a) 182:521 (2000)), as well as the efficacy of the surface bound detection chemistry.

It is known that there are many etch conditions under which macroporous silicon from n-type silicon can be made. A particular recipe using CrO₃ has been under investigation (Ouyang et al., “Enhanced Control of Porous Silicon Morphology from Macropore to Mesopore Formation,” Phys. Stat. Solidi (a) 202(8):1396-1401 (2005)). While useful for fabricating large pores exceeding 150 nm diameter, adverse side effects have been identified with its use. Because CrO₃ is a strong oxidizer, it chemically attacks the porous scaffold during etching as subsequent layers are formed deeper into the wafer. An etch pit forms near the surface layer and the width of the pore channel varies with depth. Etch times must be shortened to minimize degradation of optical quality using this additive. Moreover, the large pore diameter and corresponding interface roughness make it difficult to reproducibly achieve high optical quality devices. Hence, an etchant formulation not requiring this additive is desired.

Finally it has been reported that using basic solutions of KOH is an effective means to alter the porosity and pore diameters of both p-type silicon (DeLouise & Miller, “Trends in Porous Silicon Biomedical Devices: Tuning Microstructure and Performance Trade-Offs in Optical Biosensors,” Proc. SPIE 5357:111-125 (2004)) and n-type material (Tinsley-Brown et al., “Tuning the Pore Size and Surface Chemistry of Porous Silicon for Immunoassays,” Physica Status Solidi A, 182:547-53 (2000)).

What is lacking in the art is an understanding of how individual etching parameters (current density, etchant solution component concentrations, etc.) and post etch treatments affect porous semiconductor structure morphology (e.g., pore diameter and porosity). Obtaining an understanding of these parameters and their effects on the porous product will allow the design of etching procedures and etchant solutions for reliable and reproducible fabrication of porous semiconductor structures tuned for specific applications.

The present invention is directed to overcoming these and other deficiencies in the art.

### SUMMARY OF THE INVENTION

One aspect of the present invention relates to an etch solution including about 0-50% ethanol, about 0-25% dimethyl formamide, about 0-30% glycerol, about 5-20% hydrofluoric acid, about 0-90% water, and about 0-1% surfactant.

A second aspect of the present invention relates to a method of preparing a porous semiconductor structure. This method involves providing a semiconductor material, and etching the semiconductor material in an etch solution according to the first aspect of the present invention, under conditions effective to form the porous semiconductor structure.

A third aspect of the present invention relates to porous semiconductor structures produced according to the method of the second aspect of the present invention.

The methods of the present invention provide ways to tailor the pore morphology of porous semiconductor structures that can be used in biomedical and diagnostic devices. The porous semiconductor structures of the present invention may be used for drug delivery, tissue engineering, or for biosensors for detecting microbial pathogens, environmental toxins, and large macromolecule binding conjugates of, e.g., molecular weights exceeding 10 kDa.

### BRIEF DESCRIPTION OF THE DRAWINGS

FIG. 1 is a schematic diagram illustrating the roughness characteristics of porous semiconductor devices with pore diameters of 20 nm, 100 nm, and 150 nm.

FIG. 2 shows a reference porous structure etched in p+ silicon (0.01-0.02 ohm-cm) using an electrolyte containing 14% hydrofluoric acid in ethanol and a current density of 30 mA/cm². It has an average pore diameter of 10-20 nm, a porosity of 69.0%, and an etch rate of 22 nm/sec.

FIGS. 3A-B are a cross-sectional (FIG. 3A) and plane (FIG. 3B) SEM image of a microcavity etched in a 5% HF, 0.05% Pluronic L31 solution.

FIGS. 4A-F are SEM images of porous silicon structures produced at a current density of 30 mA/cm² using etchant #5 (FIG. 4A), etchant #2 (FIG. 4B), etchant #12 (FIG. 4C), etchant #12S (FIG. 4D), etchant #23 (FIG. 4E), and etchant #27 (FIG. 4F). The porous structure shown in FIG. 4A has an average pore diameter of 12.7 nm, a porosity of 40.0%, and was etched on n+ silicon (0.01-0.02 ohm-cm) at an etch rate of 51.5 nm/sec using 30 mA/cm². The microcavity structure shown in FIG. 4B has an average pore diameter of 19.5 nm, a porosity of 42.0%, and was etched on n+ silicon (0.01-0.02 ohm-cm) at an etch rate of 51.5 nm/sec using 30 mA/cm². The microcavity structure shown in FIG. 4C has an average pore diameter of 37.5 nm, a porosity of 58.3%, and was etched on n+ silicon (0.01-0.02 ohm-cm) at an etch rate of 49.4 nm/sec using 30 mA/cm². The microcavity structure shown in FIG. 4D has an average pore diameter of 20.5 nm, a porosity of 36.0%, and was etched on n+ silicon (0.01-0.02 ohm-cm) at an etch rate of 51.5 nm/sec using 30 mA/cm². The microcavity structure shown in FIG. 4E has an average pore diameter of 42.9 nm, a porosity of 67.3%, and was etched on n+ silicon (0.01-0.02 ohm-cm) at an etch rate of 50.4 nm/sec using 30 mA/cm². The microcavity structure shown in FIG. 4F has an average pore diameter of 82.6 nm, a porosity of 79.1%, and was etched on n+ silicon (0.01-0.02 ohm-cm) at an etch rate of 44.3 nm/sec using 30 mA/cm². Etchant #12, a yellow solution, contains Cr⁶⁺ dissociated from CrO₃. The addition of glycerol and ethanol in etchant #12S reduced Cr⁶⁺ to Cr³⁺, producing a green solution, and resulted in a less effective etchant for making large pores. Note that the scale of each SEM figure may differ.

FIGS. 5A-5D are SEM images of microcavity structures produced at a current density of 40 mA/cm² using etchant #17 with (FIGS. 5B and 5D) and without (FIGS. 5A and 5C) a post etch KOH treatment. The microcavity structure shown in FIGS. 5A and 5C has an average pore diameter of 29.1 nm, a porosity of 71%, and was etched on n+ silicon (0.01-0.02 ohm-cm) at an etch rate of 33.0 nm/sec. The microcavity structure shown in FIGS. 5B and 5D has an average pore diameter of 39.1 nm, indicating that KOH treatment can widen the pore diameter. Note that the scale of each SEM figure may differ.

FIG. 6 is a series of graphs demonstrating the effect of current density, ethanol, DMF, and glycerol on etch rate.

FIG. 7 is a series of graphs demonstrating the effect of current density, ethanol, DMF, and glycerol on porosity.

FIG. 8 is a series of graphs demonstrating the effect of current density, ethanol, DMF, and glycerol on pore diameter.

FIG. 9 is a series of graphs demonstrating the effect of current density, ethanol, DMF, and glycerol on the porosity at 30 mA/cm² compared to the porosity at 10 mA/cm².

FIG. 10 is a plot of the % reflection versus wavelength of a porous silicon optical microcavity produced with n+ silicon using etchant #17 and 10 etch periods in each mirror layer. The width of the Fabry-Perot resonance dip in reflection at ˜775 nm illustrates the quality of the microcavity structure.

FIGS. 11A-B are SEM images of microcavity structures produced using etchant #17 following surface roughening (see Table 8). FIG. 11A shows a microcavity structure produced at current density 15 mA/cm². It has an average pore diameter of 40 nm, a porosity of 45%, and was etched on n+ silicon (0.01-0.02 ohm-cm) at an etch rate of 20.6 nm/sec. FIG. 11B shows a microcavity structure produced at current density 40 mA/cm². It has an average pore diameter of 72 nm, a porosity of 71.0%, and was etched on n+ silicon (0.01-0.02 ohm-cm) at an etch rate of 33.0 nm/sec. Note that the scale of each SEM figure may differ.

FIG. 12 is a graph showing the blue shift in the Fabry-Perot resonance dip in response to KOH exposure, indicating increase in porosity.

FIG. 13 is an SEM showing a cross-sectional view of the microcavity structure corresponding to the optical response shown in FIG. 12.

FIG. 14 is an SEM showing the top view of a porous structure produced from n+silicon etched using etchant #27 at 60 mA/cm².

FIG. 15 is an SEM showing a cross-sectional view of the porous structure shown in FIG. 14.

FIG. 16 is a cross-sectional SEM image (right) of a typical microcavity device, and a graph (left) illustrating the resulting white light reflection (dips) and photoluminescence (peaks).

FIG. 17 is a graph illustrating simulations of the optical shift in the resonance peak of a mesoporous microcavity device as the pores fill with water.

FIGS. 18A-C are reflection spectra of a microcavity with 66/84% porosity before and after oxidation (FIG. 18A), and two oxidized microcavities with 71/84% porosity (FIGS. 18B-C). These results illustrate the benefit of adding more mirror layers to higher porosity devices.

FIG. 19 is a series of reflection spectra for as-etched λ/2 microcavities as a function of the number of mirror layers. Mirror layers were fabricated with 20/70 mA/cm², yielding 66/84% porosity.

FIG. 20 is an SEM image of the surface of a mesoporous microcavity showing a pore diameter of 20-30 nm.

FIGS. 21 A-B are graphs illustrating the effect on the reflectance spectra of a microcavity exposed to 1.5 mM KOH in aqueous-ethanol for 15 minutes. As shown in FIG. 21A, exposing a λ/2 p+ mesoporous microcavity to a 1.5 mM KOH treatment for 15 minutes induced a 63 nm blue shift. Oxidation caused an additional ˜80 nm shift, yielding a total blue shift of ˜142 nm, and the microcavity was ˜20% less reflective. As illustrated in FIG. 21B, in comparison, oxidation caused a 96 nm blue shift in the control sample but considerably less reduction in cavity Q factor and overall reflectivity compared to the KOH treated sample.

FIGS. 22A-B are graphs of the blue shift versus KOH time and molarity (FIG. 22A), and the blue shift normalized to exposure illustrating a two-step etch mechanism (FIG. 22B).

FIGS. 23A-B are graphs of the reflectance spectra (FIG. 23A) and photoluminescence (FIG. 23B) for a KOH treated microcavity compared to a control. Nearly identical reflectance spectra were observed for both microcavities.

FIGS. 24A-B are graphs of the absorbance intensity indicating the relative amount of conjugation product of three microcavity samples as a function of KOH exposure (FIG. 24A), and the shift in the microcavity optical response following the GST conjugation reactions (FIG. 24B).

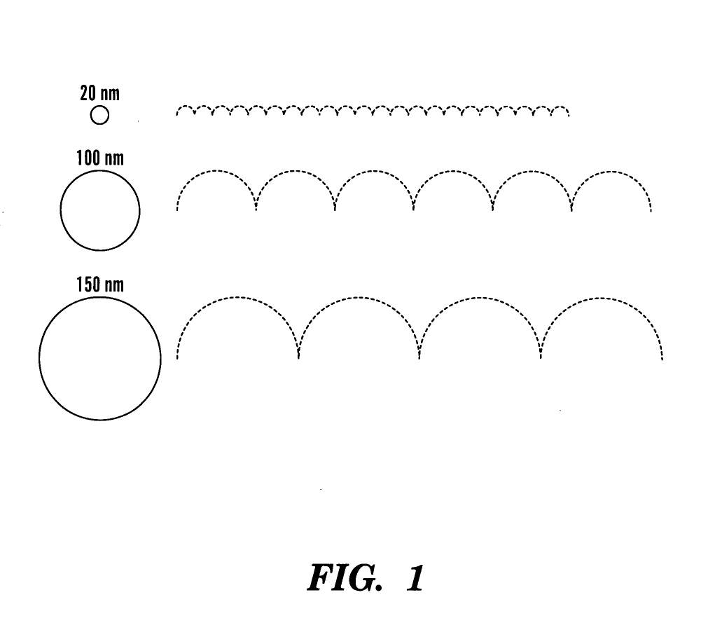

### DETAILED DESCRIPTION OF THE INVENTION

The present invention relates to chemical formulations and processes for tuning the pore morphology of an electrochemically fabricated porous semiconductor device covering any sensor detection modality (electrical or optical) requiring infiltration through the porous matrix, particularly optical devices such as Rugate filters, Bragg mirrors, dielectric mirrors, Fabry-Perot microcavities, and thin film interference devices or other biomedical applications of porous silicon where pore infiltration is a concern, such as in immobilized enzyme supports, biofiltration, drug delivery, and cell attachment scaffolding for tissue engineering. Semiconductor materials include un-doped silicon, p-doped silicon, n-doped silicon, and silicon alloys. Examples of suitable semiconductor materials are described in PCT Application WO 02/068957 to Chan et al., which is hereby incorporated by reference in its entirety. Pore diameter and porosity are a complex function of current density, silicon doping level, and etchant formulation.

Generally, the etching process involves introducing the semiconductor material (to be etched) into an etching cell that includes an anode and a cathode. An etchant is introduced into the etch cell (providing contact between anode and cathode) and a current is applied to initiate the electrochemical etch process. A constant current may be applied to produce, for example, single layer semiconductor materials. Alternatively, current through the cell can be adjusted over a time course to create periodic porous materials, such as Bragg reflectors. For example, multilayer films of alternating porosity may be fabricated by cycling between a higher and lower density, for example between about 20 mA/cm² and about 60 mA/cm². After etching, the porous silicon sample is removed from the etch cell, rinsed with ethanol, then water, and dried under a stream of N₂ gas. Samples of various thickness are prepared by using a constant current density of and varying the etch time from 1 to 300 seconds.

Electropolishing the surface of the silicon material before fabricating the porous semiconductor structure creates pore nucleation sites, which help guide pore channel growth. Post etch processing using chemical bases can also be used to further alter the porous morphology. For example, to remove nanostructured features that fill the pore channels or to widen the pore diameters, porous silicon films may be treated with a chemical base (e.g. 0.05 mM-0.5 M KOH) post etch process as described herein. A quantitative relation exists between the amount of porous silicon material removed with exposure time and base concentration. Typically, a high concentration aqueous base stock solution is diluted with 95% ethanol to insure the base solution can infiltrate porous silicon. After base exposure, samples are rinsed in ethanol, then water, and dried under a stream of N₂ gas.

The chemical etch formulations of the present invention may include water, hydrofluoric acid, glycerol, ethanol, dimelthylformamide, and additives including surfactants and oxidizing agents. These formulations enable the systematic tailoring of pore diameter and porosity of porous silicon fabricated from n+ silicon (0.01-0.02 ohm-cm).

One aspect of the present invention relates to an etch solution 0 including about 0-50% ethanol, about 0-25% dimethyl formamide, about 0-30% glycerol, about 5-20% hydrofluoric acid, about 0-90% water, and about 0-1% surfactant.

Hydrofluoric acid concentrations disclosed herein refer to pure hydrofluoric acid. One of skill in the art will readily understand how to use diluted hydrofluoric acid solutions in the etch solutions of the present invention, such that the total hydrofluoric acid solution falls within the desired range. Deionized water and distilled water are preferred. The percentages of the components of the etchant solutions of the present invention refer percent by weight.

Any suitable surfactant may be used in combination with the other etchant components. Exemplary surfactants include, without limitation, nonionic surfactants including alkylphenol ethoxylate, alcohol ethoxylates, sorbitan esters (Rheodol series), ethylene oxide/polyethylene oxide block polymers (Pluronic series, e.g., F108, F38, P105, L101, and L31, or Dowfax series), and alkylpolyglucosides (Triton series); cationic surfactants including all quaternary ammonium compounds; and anionic surfactants including alkyl, aryl, and ether sulfates and phosphates.

Suitable oxidizing agents according to the present invention include, without limitation, chromium trioxide, ammonium persulfate, osmium tetroxide, and potassium permanganate.

Using the etchant formulations of the present invention, pore diameter can be tuned over a range from 20 nm to 150 nm, which is of particular biochemical interest. The value of the current density at which the electropolishing limit is attained depends on the etchant formulation. Generally, lowering the HF concentration increases porosity and, hence, lowers the current density at which electropolishing occurs; and for a fixed HF concentration, adding solvents increases porosity and decreases pore size.

As described in the Examples, the preferred ranges of the components will vary according to the nature of the porous semiconductor material that is to be made. The properties of the porous semiconductor material can be controlled by selecting appropriate etch conditions, including etching composition and current density.

Preferred etchant solutions include those described in the Examples. According to one embodiment, the etchant solutions include between about 20 to about 80% water, about 5 to about 20% hydrofluoric acid, about 10 to about 50% ethanol, about 0 to about 30% DMF, about 0 to about 30% glycerol, and about 0.01 to about 0.3% surfactant.

### EXAMPLES

The following examples are intended to illustrate, but by no means are intended to limit, the scope of the present invention as set forth in the appended claims.

### Example 1

### Determination of the Etching Parameter Space for a 20% HF Formulation

A design of experiments (DOE) approach was taken to understand the etching parameter space for a formulation consisting of 20% hydrofluoric acid (HF). The HF concentration was kept constant so that the effects of solvent level could be better determined. It is well documented that raising HF levels increases etch rate and lowers porosity in p+ silicon. Lower levels of HF decrease the etch rate and increase the porosity. Hence, with lower levels of HF, larger pore diameters are achieved and the electropolishing limit is reached at lower current densities.

A two level ½ factorial DOE was conducted with four control factors including the solvents comprising the etchant formulation (including ethanol (10 and 25%), DMF (10 and 25%), and glycerol (0 and 30%)) and the current density (10 and 30 mA/cm²). The glycerol was utilized to raise viscosity, and ethanol and DMF to alter the surface tension of the etching solution. All solvents will lessen the dielectric constant and surface tension relative to water, but ethanol will particularly do so. Physical properties of the solvents are listed in Table 1A.

TABLE 1A
Solvent physical properties.

| Solvent | Surface Tension (dynes/cm) | Dielectric Constant |
|---|---|---|
| Water | 72.8 | 79.2 |
| Ethanol | 22.1 | 24.3 |
| DMF | 37.1 | 38.3 |
| Glycerol | 64.0 | 47.2 |
| 0.1% aqueous Pluronic | 41.0 | na |
| F108 | | |

The responses for this DOE included porosity (% P), etch rate measured by gravimetric means, and pore diameter determined by SEM. An additional response analyzed was the value of the porosity at 30 mA/cm² relative to that at 10 mA/cm² (“% P Ratio 30/10 mA/cm²”). To simplify multilayer device fabrication (e.g., Bragg mirror, microcavity devices) it is desired that the value of this response be greater than 2-3% and positively correlated with the current density. Eight unique etching formulations, shown in Table 1B, were investigated to complete the DOE. In addition to these, during the period of time over which the DOE was conducted, more than 30 total etchant formulations were studied to assess the effect of ammonium persulfate (APS), CrO₃, Pluronic F108, L31, F38, L101, and P105 surfactants, DMSO, and HF concentration. The formulations for etchants that provided significant learning are also included in Table 1B. All etchant formulations were evaluated using single side polished n+ (0.01-0.02 ohm-cm) Si (100) wafers that were cleaned prior to etching by: N₂ blow dry to remove dust, dip in diluted HF to remove oxide, water rinse, and N₂ blow dry. A single layer porous silicon film was etched for either 100 seconds or 300 seconds.

TABLE 1B

| | | | | | | | |
|---|---|---|---|---|---|---|---|
| Etchant | ethanol | DMF | glycerol | H.F. | water | current | Other |

DOE etchant formulas.

| | | | | | | |
|---|---|---|---|---|---|---|
| 7 | 10 | 25 | 30 | 20 | 15 | 10 |
| 5 | 10 | 10 | 30 | 20 | 30 | 30 |
| 1 | 10 | 10 | 0 | 20 | 60 | 10 |
| 2 | 25 | 10 | 0 | 20 | 45 | 30 |
| 4 | 25 | 25 | 0 | 20 | 30 | 10 |
| 3 | 10 | 25 | 0 | 20 | 45 | 30 |
| 6 | 25 | 10 | 30 | 20 | 15 | 10 |
| 8 | 25 | 25 | 30 | 20 | 0 | 30 |

Additional Formulations

| | | | | | | | |
|---|---|---|---|---|---|---|---|
| 12 | 0 | 0 | 0 | 20 | 80 | 30 | 0.2% CrO₃ |
| 12S | 10 | 0 | 30 | 20 | 40 | 30 | 0.2% CrO₃ |
| 15 | 0 | 0 | 0 | 20 | 80 | 30 | 0.3% APS |
| 15M | 0 | 0 | 0 | 20 | 80 | 30 | 0.3% APS, |
| | | | | | | | 0.1% |
| | | | | | | | Pluronic |
| | | | | | | | F108 |
| 17 | 35 | 0 | 30 | 15 | 20 | 40 | |
| 23 | 20 | 0 | 0 | 15 | 65 | 60 | |
| 27 | 0 | 0 | 0 | 15 | 85 | 60 | 0.1% |
| | | | | | | | Pluronic |
| | | | | | | | F108 |
| | 50 | 0 | 0 | 10 | 40 | | |
| | 0 | 0 | 0 | 5 | 95 | | 0.01-0.1% |
| | | | | | | | L31 |

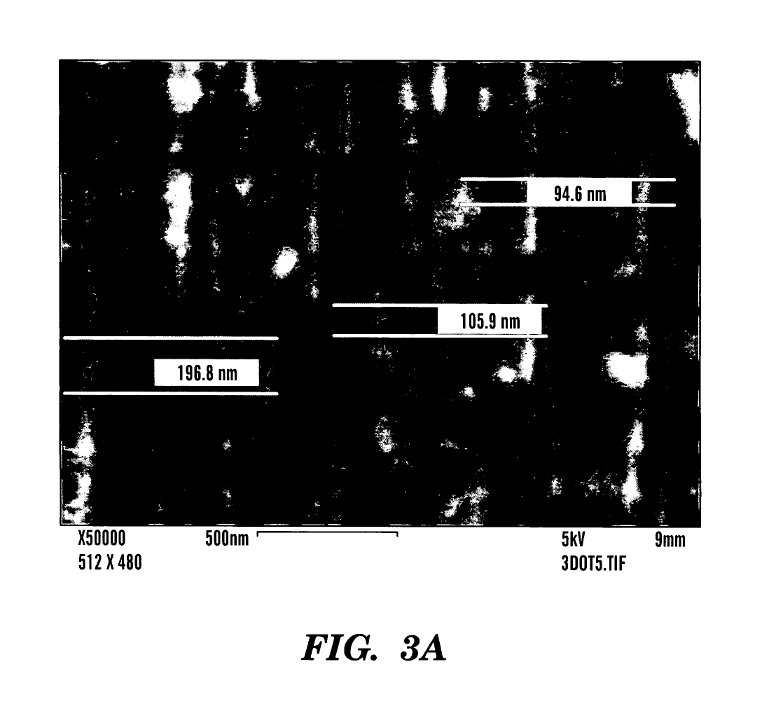

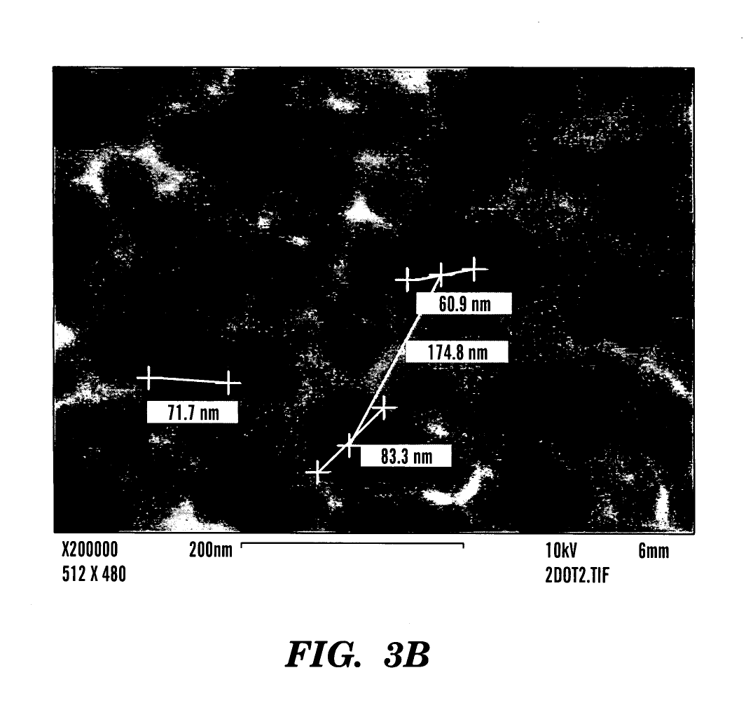

SEM images of a microcavity etched with a 5% HF, 0.05% Pluronic ution are shown in FIGS. 3A-B.

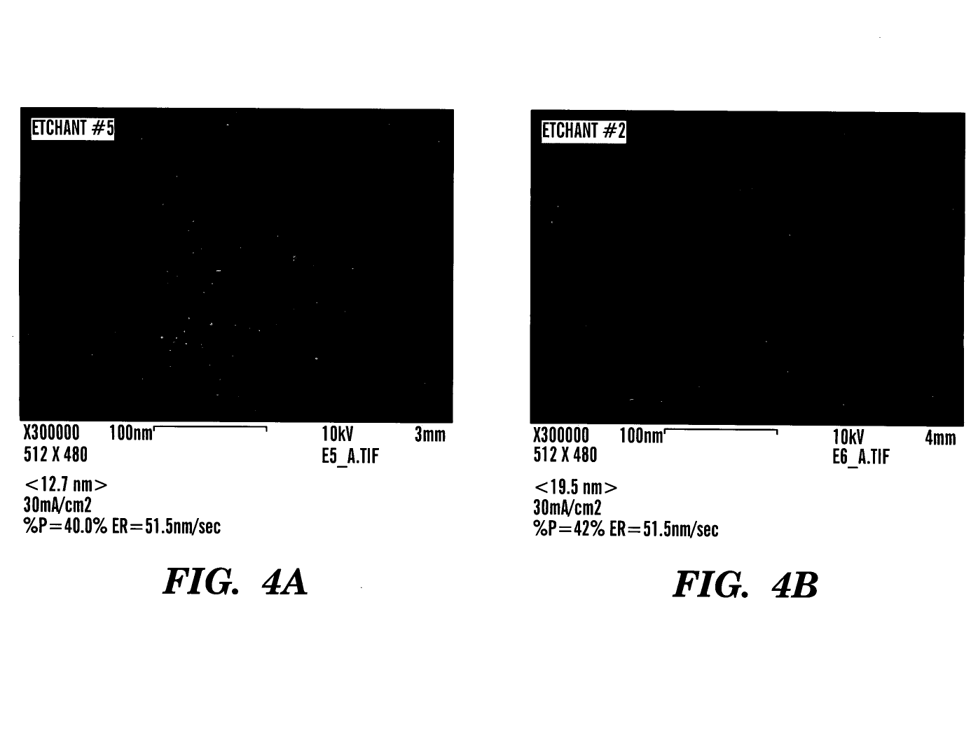

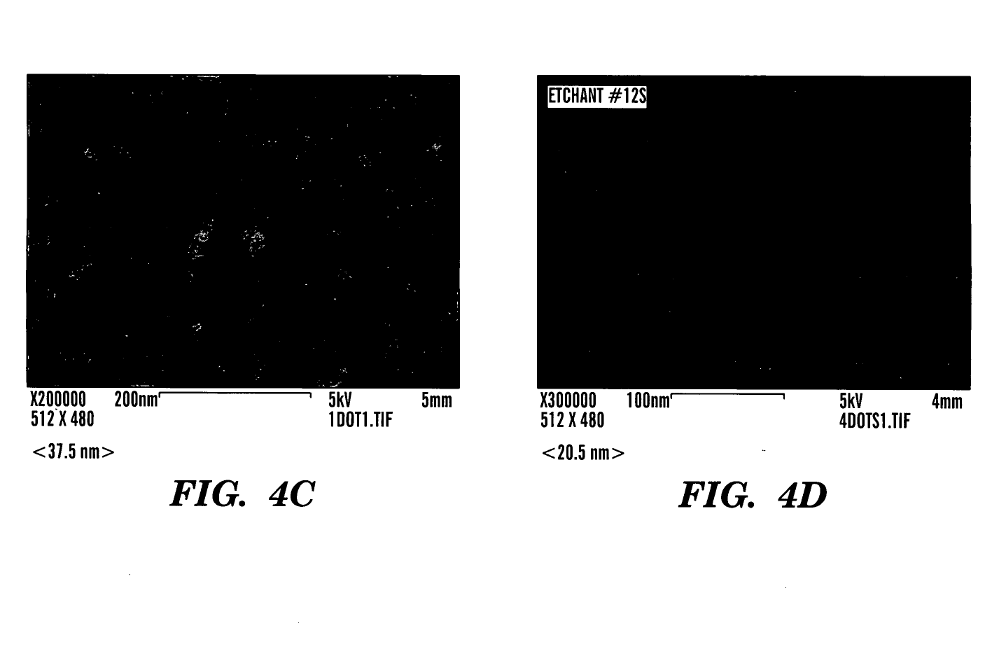

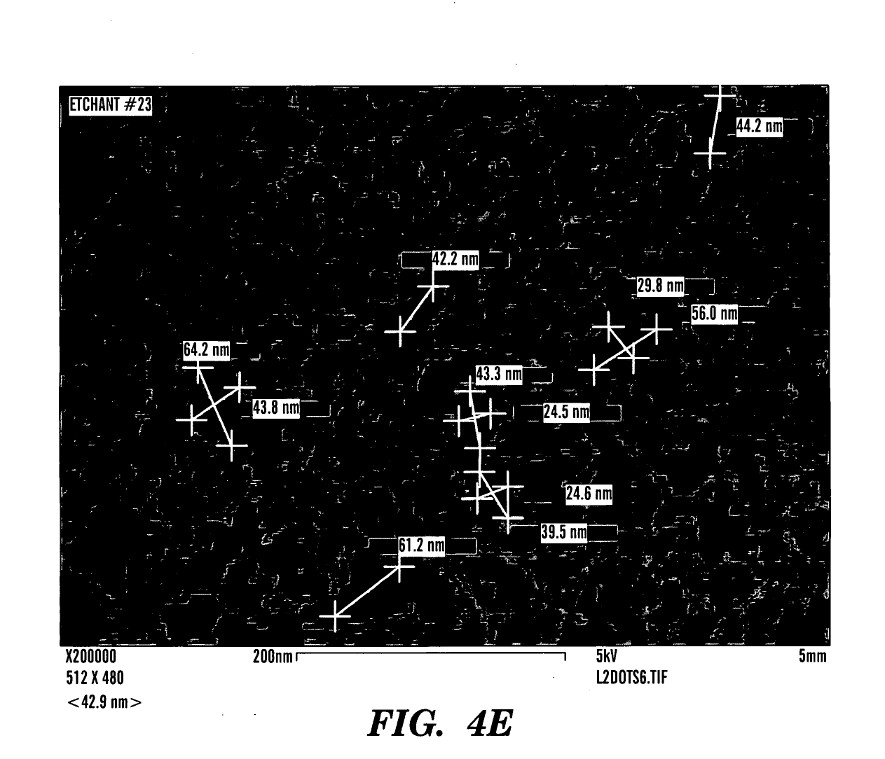

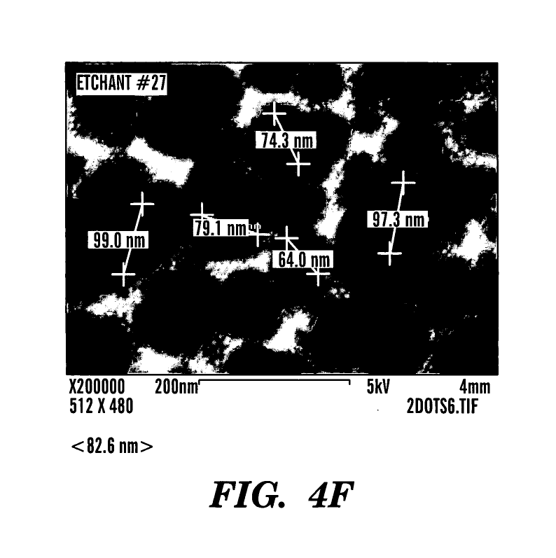

The SEM images for etchant #2 (FIG. 4B), #5 (FIG. 4A), #12 FIG. 4C), and #12S (all at 30 mA/cm²) shown in FIG. 4 illustrate how strongly pore diameter depends on etchant composition.

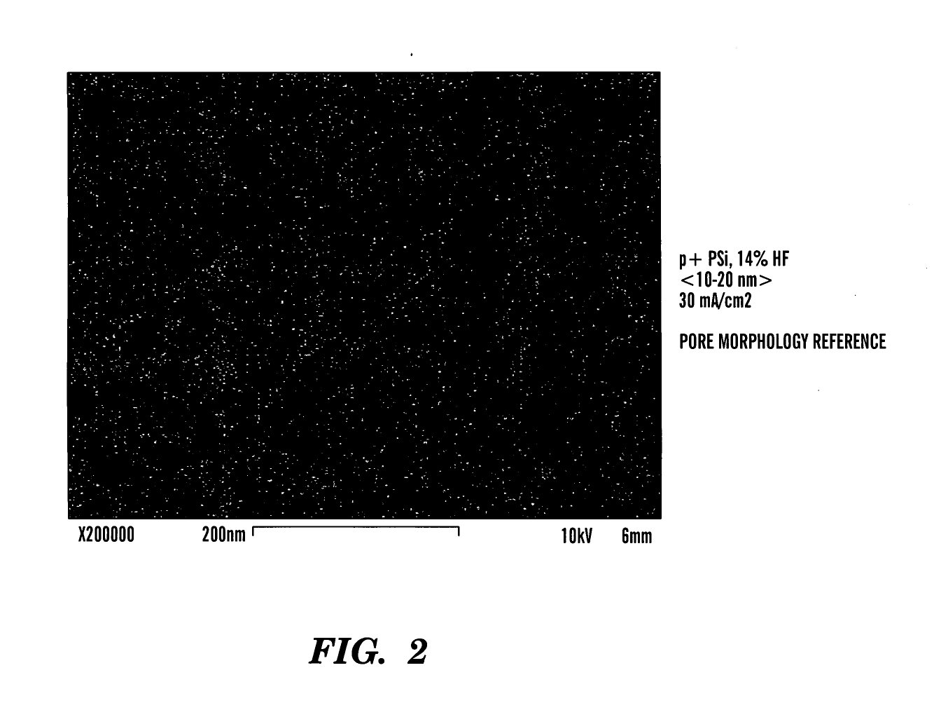

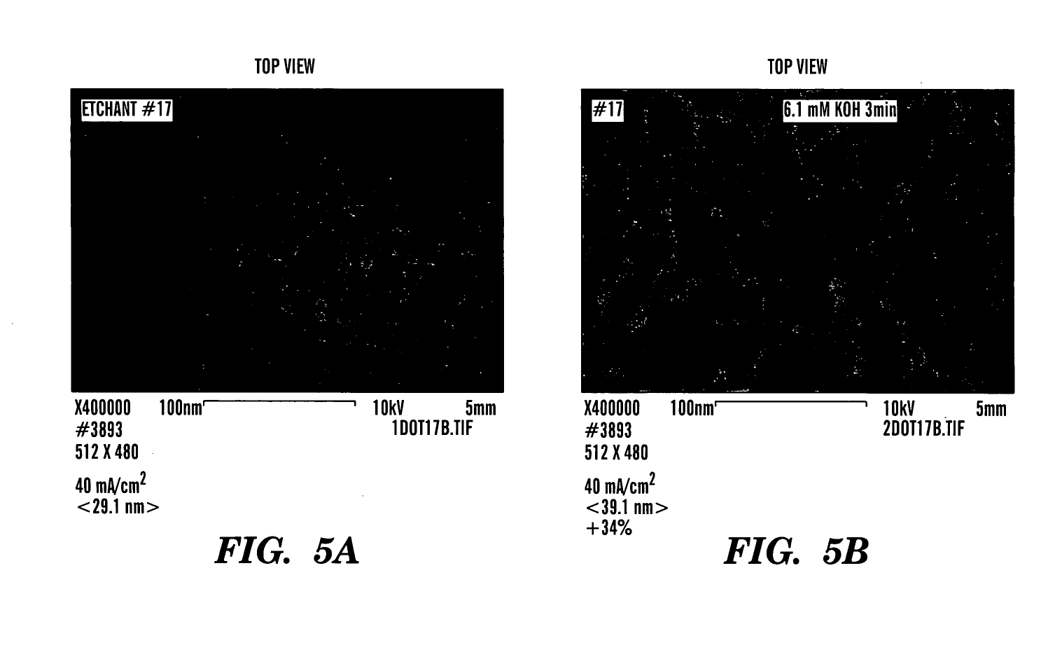

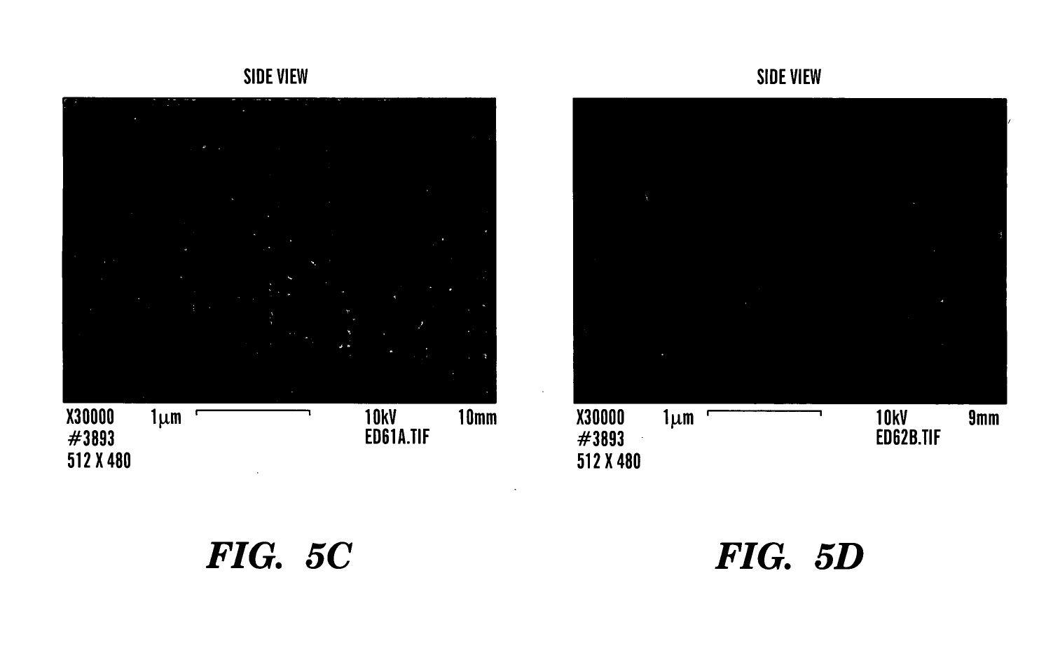

Images for etchant #17 (FIGS. 5A-D) also illustrate the significant effect that post etch KOH treatment has on pore morphology. A rounding of the pores is evident, as is a pore widening of ˜34% (see FIGS. 5B and 5D). The measured and DOE predicted etch rate and porosity of #17 are also illustrated in FIG. 5. A typical mesoporous p+ image is shown in FIG. 2 for reference. In comparing images, it is important to note the magnification and scale.

It is of interest to note that in the SEM images shown in FIGS. 4-5, the dark holes represent developed pore channels that extend through the porous silicon (“PSi”) layer to the silicon wafer interface, as seen in the side view images for etchant #17 (FIGS. 5C and 5D). The lighter colored pores represent nucleation sites that initiated but current density was not sustained and pore channel growth ceased. Evidence that underdeveloped pore channels occur at the surface layer of a polished wafer and a process to avoid this is described in Example 6.

In relation to optimizing pore morphology, a generally accepted relation between porosity and pore diameter is described. Small pore diameter is associated with higher porosity. This relation describes a high surface area mesoporous material comprising a dendritic pore channel morphology that results from the nucleation of numerous pore channels that sustain current conduction along which etching occurs. Large pore diameter is associated with lower porosity. This relation describes a lower surface area macroporous material consisting of fewer pore channels and a smoother pore channel morphology. This results from the tendency for only a few of the nucleated pore channels to sustain current conduction and growth.

Pore diameters resulting from this etching formulation DOE on polished wafer surfaces ranged between 10-40 nm. This is still in the mesoporous regime, but most formulations were found to yield much larger pore diameters than what is typically produced in etching standard mesoporous silicon from p+ wafers. Moreover, significant insight is gleaned from sensitivity analysis of the relationships that exist between control factors and responses.

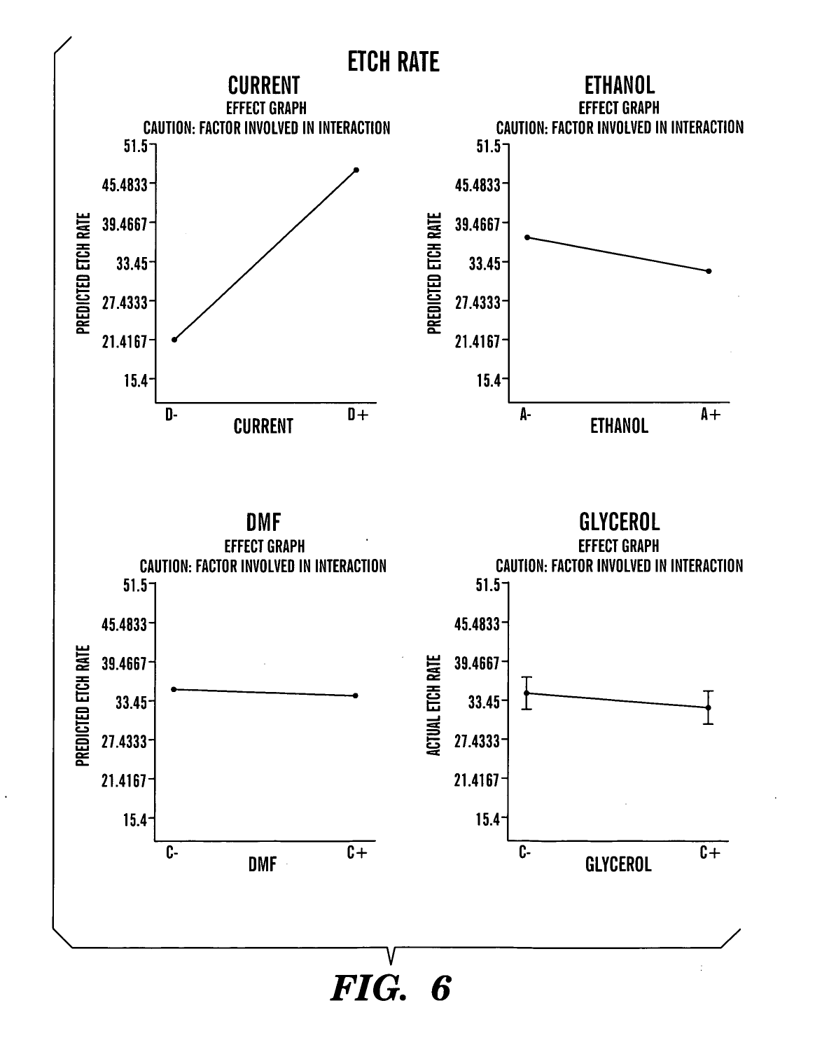

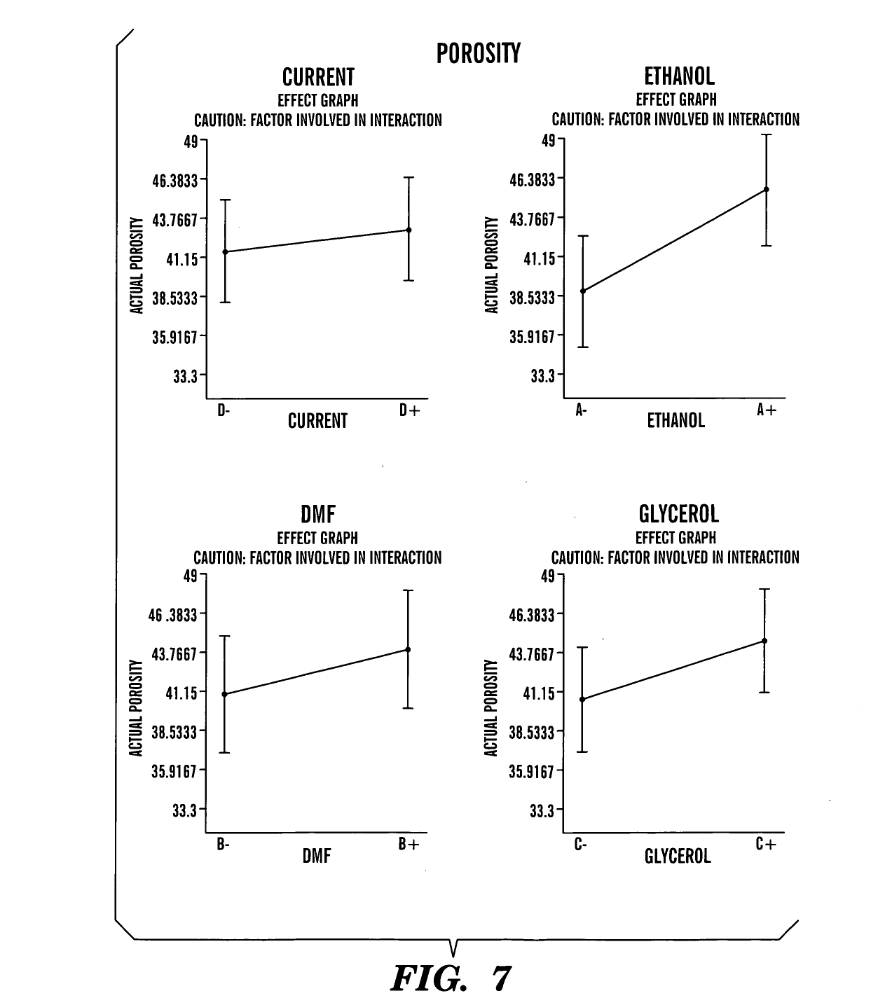

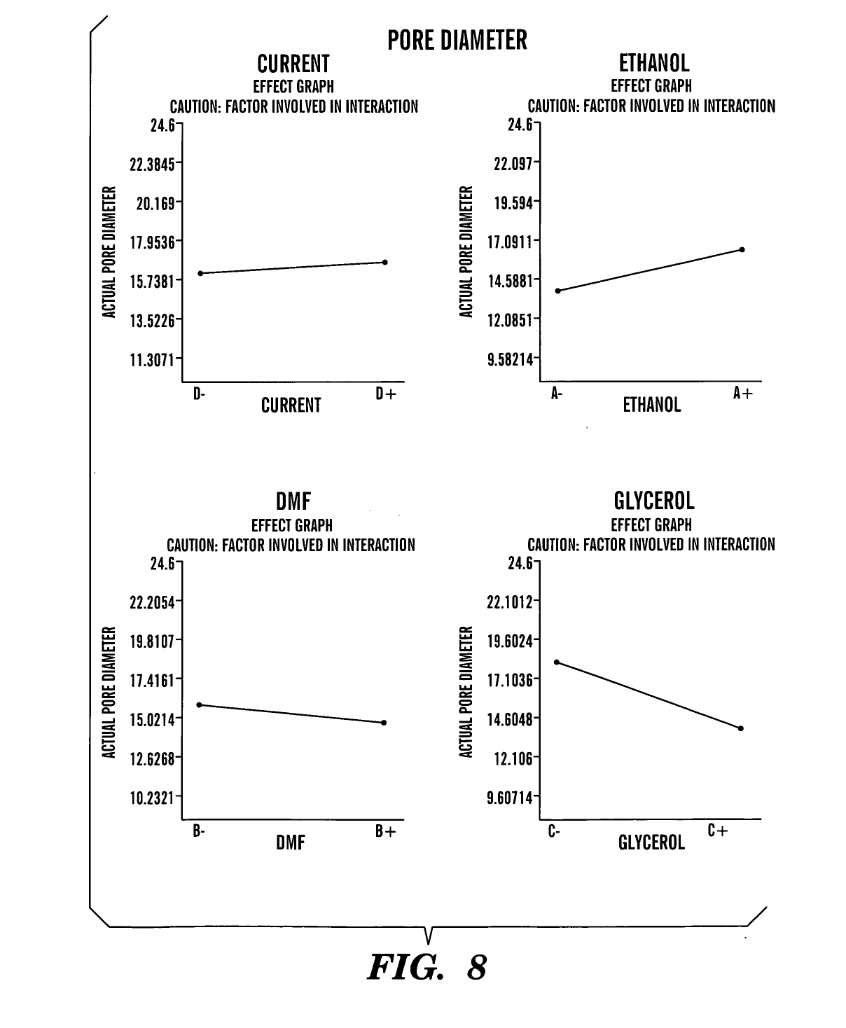

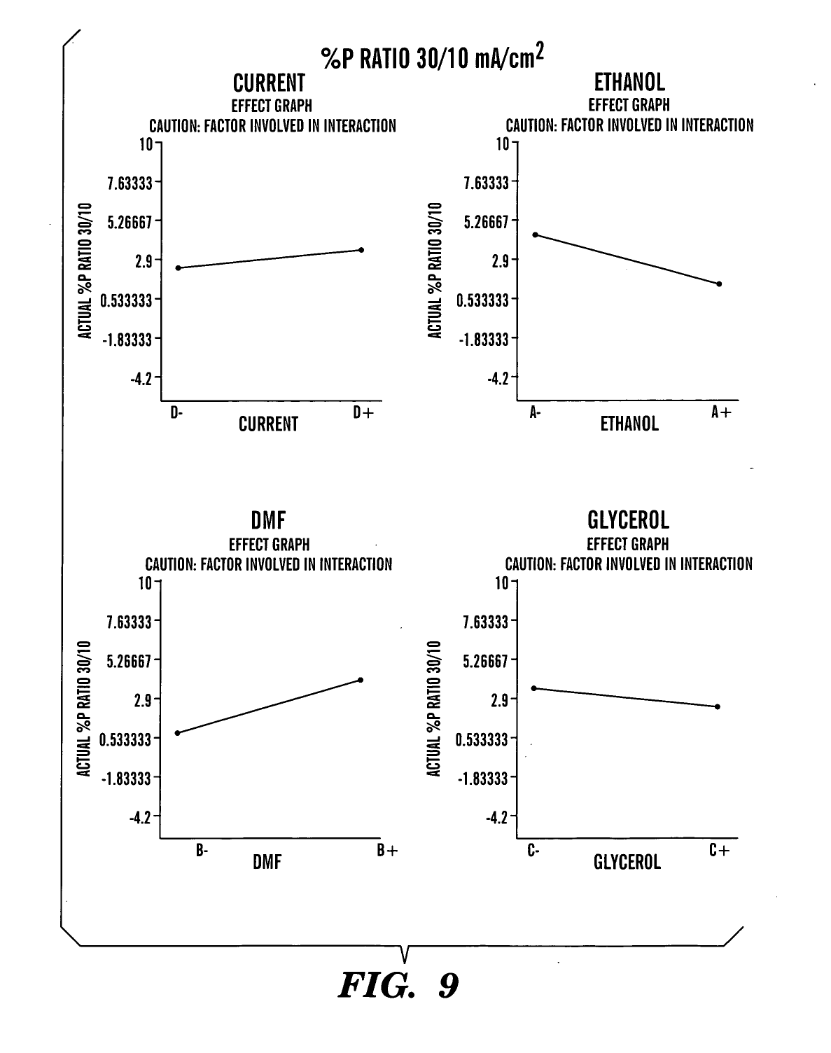

Table 2 summarizes results of the DOE sensitivity analysis of the dependence of responses on control factors. Graphs plotting the data from which this summary was produced are shown in FIGS. 6-9. A positive correlation is denoted in Table 2 by a plus sign (+) and a negative correlation is denoted by a minus sign (−). A zero indicates no dependence. The magnitude of the correlation is designated by the number of + and ‘ signs. Etch rate (FIG. 6) is highly correlated with current density, whereas the solvent levels have little effect at all, with the slight exception of ethanol and glycerol, which slightly lower the etch rate. Porosity (FIG. 7), on the other hand, is positively correlated with all the control factors. Increasing the ethanol and glycerol concentrations raises porosity significantly. Pore diameter (FIG. 8) increases when ethanol is raised, but increasing the viscosity with glycerol decreases pore diameter. % P Ratio 30/10 mA/cm² (FIG. 9) is increased by DMF and current density, but decreased by ethanol and glycerol. An important consideration in choosing an optimum formulation for porous semiconductor structure formation is the ability to have porosity be positively correlated with current density. Raising the DMF concentration ensures that the porosity increases with current density, where the opposite relation occurs with ethanol.

TABLE 2
Sensitivity of control factors on responses.
Responses

| Control | | | Pore | % P 30/10 |
|---|---|---|---|---|
| Factors | Etch Rate | Porosity | Diameter | mA/cm² |
| Current | ++++ | + | + | + |
| density | | | | |
| Ethanol | − | +++ | ++ | −− |
| DMF | 0 | + | − | ++ |
| Glycerol | − | ++ | −− | − |

Examples 2-5 describe unique etchant formulations designed to produce porous semiconductor structures of a specific morphology type.

### Example 2

### Etchant Formula to Maximize Pore Diameter and Maximize Porosity

Table 3 illustrates that to maximize pore diameter and maximize porosity while allowing the other parameters to vary within range, an optimized formulation includes about 25% ethanol, about 10-11% DMF, and about 0% glycerol, in water. This represents the maximum level of ethanol and the lowest levels of DMF and glycerol, as studied in this set of experiments.

TABLE 3
Etchant formula to maximize pore diameter and maximize porosity.
Constraints

| | | Lower | Upper | Lower | Upper | |
|---|---|---|---|---|---|---|
| Name | Goal | Limit | Limit | Weight | Weight | Importance |
| Ethanol | 10.00 . . . 25.00 | 10 | 25 | 1 | 1 | 0 |
| DMF | 10.00 . . . 25.00 | 10 | 25 | 1 | 1 | 0 |
| Glycerol | 0.00 . . . 30.00 | 0 | 30 | 1 | 1 | 0 |
| current | 10.00 . . . 30.00 | 10 | 30 | 1 | 1 | 0 |
| etch rate | 15.4 . . . 60 | 15.4 | 60 | 1 | 1 | 0 |
| porosity | ≧49 | 17 | 49 | 1 | 1 | 3 |
| pore diameter | ≧30 | 11.8 | 30 | 1 | 1 | 3 |
| % P Ratio 30/10 | 2 . . . 11 | 2 | 11 | 1 | 1 | 0 |

Solutions

| | | | | | | | % P Ratio | |
|---|---|---|---|---|---|---|---|---|
| ethanol | DMF | glycerol | current | etch rate | porosity | pore dia. | 30/10 | |
| 3.1 | 25.00 | 11.95 | 0.00 | 24.88 | 42.8049 | 44.8556 | 19.6605 | 2 |
| 3.2 | 24.79 | 11.35 | 0.00 | 25.54 | 44.0417 | 44.5199 | 19.75 | 2 |
| 3.3 | 24.42 | 10.98 | 0.00 | 25.70 | 44.4068 | 44.2068 | 19.8278 | 1.99999 |
| 3.4 | 24.38 | 10.45 | 0.00 | 26.55 | 45.9339 | 43.9822 | 19.8921 | 1.99999 |

### Example 3

### Etchant Formula to Maximize Pore Diameter and Minimize Porosity (Large Mesoporous and Macroporous)

Table 4 illustrates that to maintain a maximum pore diameter but to minimize porosity (the conditions indicative of macroporous silicon) while allowing the other parameters to vary within range, an optimized formula includes about 10% ethanol and about 10% DMF, in water, which are the lower limits of all the solvent systems studied in this set of experiments. This data teaches that lowering solvent load and viscosity are essential for maximizing pore diameter. Solvents and a high viscosity enhance pore channel nucleation, and sustained etching along multiple pathways leads to higher porosity.

TABLE 4
Etchant formula to maximize pore diameter and minimize
porosity (large mesoporous and macroporous).

| | | Lower | Upper | Lower | Upper | |
|---|---|---|---|---|---|---|
| Name | Goal | Limit | Limit | Weight | Weight | Importance |
| Ethanol | 10.00 . . . 25.00 | 10 | 25 | 1 | 1 | 0 |
| DMF | 10.00 . . . 25.00 | 10 | 25 | 1 | 1 | 0 |
| Glycerol | 0.00 . . . 30.00 | 0 | 30 | 1 | 1 | 0 |
| current | 10.00 . . . 30.00 | 10 | 30 | 1 | 1 | 0 |
| etch rate | 15.4 . . . 60 | 15.4 | 60 | 1 | 1 | 0 |
| porosity | ≦17 | 17 | 49 | 1 | 1 | 2 |
| pore diameter | ≧30 | 11.8 | 30 | 1 | 1 | 2 |
| % P Ratio 30-10 | 2 . . . 11 | 2 | 11 | 1 | 1 | 0 |

Solutions

| | | | | | | | % P Ratio | |
|---|---|---|---|---|---|---|---|---|
| ethanol | DMF | glycerol | current | etch rate | porosity | pore dia. | 30/10 | |
| 4.1 | 10.00 | 10.74 | 0.00 | 30.00 | 48.8448 | 39.9198 | 20.0701 | 4.18422 |
| 4.2 | 10.00 | 10.01 | 0.00 | 27.59 | 45.4523 | 39.3578 | 19.5634 | 4.00143 |
| 4.3 | 10.00 | 10.00 | 0.00 | 26.79 | 44.3161 | 39.2127 | 19.3066 | 3.99986 |
| 4.4 | 10.00 | 11.70 | 0.04 | 29.25 | 47.778 | 39.9338 | 19.4601 | 4.41172 |

### Example 4

### Etchant Formula to Minimize Pore Diameter and Maximize Porosity (Mesoporous)

Table 5 illustrates that to minimize pore diameter and maximize porosity (the conditions indicative of mesoporous silicon) while allowing the other parameters to vary within range, an optimized formula includes about 25% ethanol, about 25% DMF, and about 30% glycerol, in water, the maximum solvent concentration studied in this set of experiments. This teaches that raising the viscosity and solvent load enhances pore nucleation and the ability of numerous pore channels to sustain etch current and growth.

TABLE 5
Etchant formula to minimize pore diameter and maximize porosity (mesopore).
Constraints

| | | Lower | Upper | Lower | Upper | |
|---|---|---|---|---|---|---|
| Name | Goal | Limit | Limit | Weight | Weight | Importance |
| Ethanol | 10.00 . . . 25.00 | 10 | 25 | 1 | 1 | 0 |
| DMF | 10.00 . . . 25.00 | 10 | 25 | 1 | 1 | 0 |
| Glycerol | 0.00 . . . 30.00 | 0 | 30 | 1 | 1 | 0 |
| current | 10.00 . . . 30.00 | 10 | 30 | 1 | 1 | 0 |
| etch rate | 15.4 . . . 60 | 15.4 | 60 | 1 | 1 | 0 |
| porosity | ≧49 | 17 | 49 | 1 | 1 | 3 |
| pore diameter | ≦11.8 | 11.8 | 30 | 1 | 1 | 3 |
| % P Ratio 30/10 | 2 . . . 11 | 2 | 11 | 1 | 1 | 0 |

Solutions

| | | | | | | | % P Ratio | |
|---|---|---|---|---|---|---|---|---|
| ethanol | DMF | glycerol | current | etch rate | porosity | pore dia. | 30/10 | |
| 5.1 | 23.82 | 24.82 | 27.60 | 28.97 | 39.5926 | 49.3165 | 11.6656 | 4.35296 |
| 5.2 | 24.90 | 25.00 | 29.36 | 25.57 | 34.4689 | 49.0824 | 11.7424 | 3.72544 |
| 5.3 | 24.20 | 24.71 | 28.18 | 28.90 | 39.2351 | 49.4315 | 11.7723 | 4.23819 |
| 5.4 | 22.62 | 24.93 | 23.21 | 28.79 | 40.5162 | 49.003 | 11.7103 | 4.75284 |

### Example 5

### Etchant Formula to Minimize Pore Diameter and Minimize Porosity, ˜10 mA/cm²

Table 6A illustrates that to minimize pore diameter and minimize porosity while allowing the other parameters to vary within range, an optimized formula includes about 10% ethanol, about 25% DMF, and about 5-12% DMF, in water. This result is achieved, however, at lower current densities of 10 mA/cm². Table 6B illustrates that to achieve this morphology at higher current density (e.g., ˜30 mA/cm²) the glycerol concentration must be increased to ˜30%, the maximum studied; however, the porosity consequently increases somewhat.

TABLE 6A
Etchant formula to minimize pore diameter and minimize
porosity at current density ˜10 mA/cm².
Constraints

| | | Lower | Upper | Lower | Upper | |
|---|---|---|---|---|---|---|
| Name | Goal | Limit | Limit | Weight | Weight | Importance |
| Ethanol | 10.00 . . . 25.00 | 10 | 25 | 1 | 1 | 0 |
| DMF | 10.00 . . . 25.00 | 10 | 25 | 1 | 1 | 0 |
| Glycerol | 0.00 . . . 30.00 | 0 | 30 | 1 | 1 | 0 |
| current | 10.00 . . . 30.00 | 10 | 30 | 1 | 1 | 0 |
| etch rate | 15.4 . . . 60 | 15.4 | 60 | 1 | 1 | 0 |
| porosity | ≦17 | 17 | 49 | 1 | 1 | 3 |
| pore diameter | ≦11.8 | 11.8 | 30 | 1 | 1 | 3 |
| % P Ratio 30/10 | 2 . . . 11 | 2 | 11 | 1 | 1 | 0 |

Solutions

| | | | | | | | % P Ratio | |
|---|---|---|---|---|---|---|---|---|
| ethanol | DMF | glycerol | current | etch rate | porosity | pore dia. | 30/10 | |
| 6A.1 | 10.00 | 25.00 | 4.69 | 10.02 | 27.7381 | 34.4003 | 6.57752 | 5.32715 |
| 6A.2 | 10.00 | 25.00 | 8.27 | 10.00 | 27.8911 | 34.4324 | 5.20623 | 5.42084 |
| 6A.3 | 10.00 | 25.00 | 12.27 | 10.04 | 28.1223 | 34.4898 | 3.69725 | 5.53036 |

TABLE 6B
Etchant formula to minimize pore diameter and minimize
porosity at current density ˜30 mA/cm².
Constraints

| | | Lower | Upper | Lower | Upper | |
|---|---|---|---|---|---|---|
| Name | Goal | Limit | Limit | Weight | Weight | Importance |
| Ethanol | 10.00 . . . 25.00 | 10 | 25 | 1 | 1 | 0 |
| DMF | 10.00 . . . 25.00 | 10 | 25 | 1 | 1 | 0 |
| Glycerol | 0.00 . . . 30.00 | 0 | 30 | 1 | 1 | 0 |
| current | ≧30.00 | 10 | 30 | 1 | 1 | 3 |
| etch rate | 15.4 . . . 60 | 15.4 | 60 | 1 | 1 | 0 |
| porosity | ≦17 | 17 | 49 | 1 | 1 | 3 |
| pore diameter | ≦11.8 | 11.8 | 30 | 1 | 1 | 3 |
| % P Ratio 30/10 | 2 . . . 11 | 2 | 11 | 1 | 1 | 0 |

Solutions

| | | | | | | | % P Ratio | |
|---|---|---|---|---|---|---|---|---|
| ethanol | DMF | glycerol | current | etch rate | porosity | pore dia. | 30/10 | |
| 6B.1 | 10.00 | 24.89 | 30.00 | 29.90 | 50.5237 | 41.2421 | 7.14712 | 5.97372 |
| 6B.2 | 10.00 | 25.00 | 30.00 | 29.78 | 50.3873 | 41.1947 | 7.04533 | 5.99996 |
| 6B.3 | 10.00 | 23.66 | 29.98 | 29.98 | 50.6512 | 41.3486 | 7.64888 | 5.66763 |
| 6B.4 | 10.11 | 23.85 | 30.00 | 30.00 | 50.587 | 41.4016 | 7.61572 | 5.70035 |
| 6B.5 | 10.00 | 25.00 | 29.99 | 28.28 | 48.7588 | 40.6996 | 6.27913 | 6.00028 |

The sensitivity analysis demonstrated in Examples 2-5 illustrates the complexity of the interactions between etching formulation and morphology, from which several conclusions can be drawn. To fabricate small mesoporous material (2 nm-20 nm dia., high porosity), the etchant should maximize solvent load and raise viscosity. To make large mesoporous (20 nm-50 nm) and macroporous material (low porosity, large pore diameter), the formulation should minimize solvent load and lower viscosity. To raise the porosity of large mesoporous and macroporous materials, the solvent level, particularly ethanol, should be raised. Adding DMF ensures that a positive correlation exists between porosity and current density. A summary of the effects of ethanol, glycerol, and DMF on n+ silicon (0.1-0.2 ohm-cm) microcavities is shown in Table 7.

TABLE 7
Summary of results for n+ silicon (0.1-0.2 ohm-cm).

| | MacroPore | MacroPore | MesoPore |
|---|---|---|---|
| | (large diameter, | (large diameter, | (small diameter, |
| Solvent | low porosity) | high porosity) | high porosity) |
| Ethanol | low | high | high |
| Glycerol | low | low | high |
| DMF | low | low | high |

Taking into consideration the DOE results and significant learning from the additional formulations investigated, an optimum formulation to achieve large meso- and macroporous silicon can be defined: 0-25% ethanol, 0-10% DMF, 10-20% HF, and 0-1% surfactant. For a given current density, larger pores are formed by lowering the HF concentration. A preferred HF concentration is 15%.

### Example 6

### Pre-Etch Surface Roughening

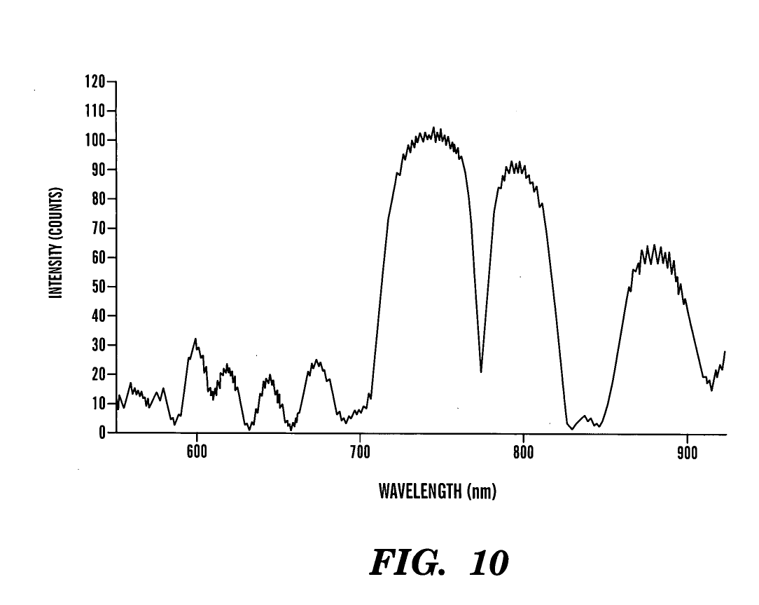

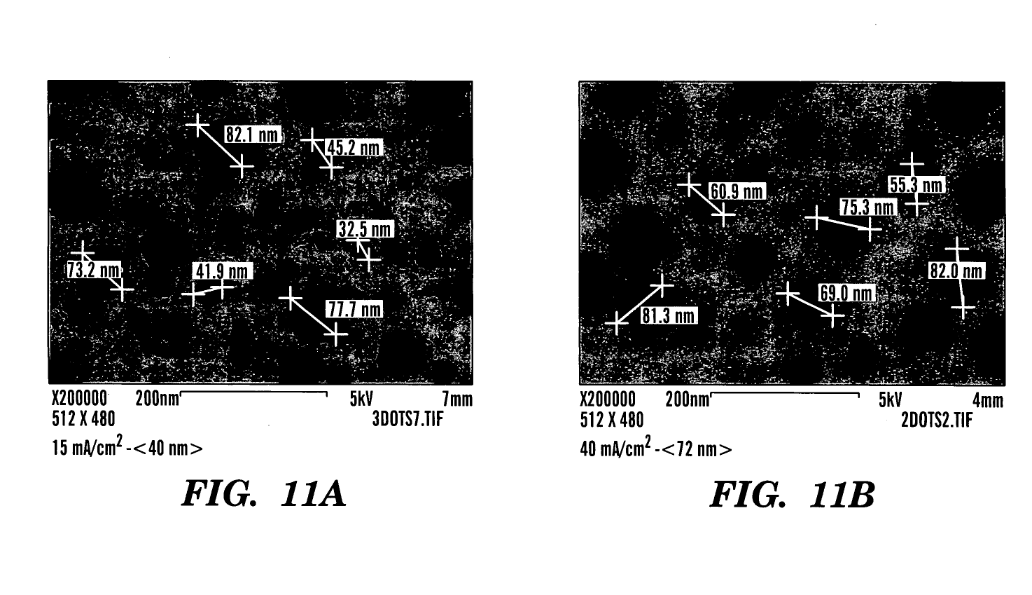

To improve the stability of pore formation and to insure sustained growth of large pore diameter to 100 nm or higher, the polished wafer surface first must be roughened. A convenient (but not sole) method to achieve this is to apply an electropolishing step prior to fabricating the porous silicon layer or multilayer structure. This phenomenon was discovered while monitoring voltages during the process of optimizing the electrochemical etch times for fabricating a λ/2 microcavity structure using etchant #17. Tables 8 and 9 illustrate the voltages (average of three independent runs) as a function of layer. Table 8 indicates the voltages used to prepare a microcavity without surface roughening. Note that the voltage for etching the first layer using a current density of 15 mA/cm² is nearly two times larger than that required to etch the second, third, and fourth layers using an equivalent current density. Table 9 illustrates that roughening the surface with an electropolishing step prior to etching the microcavity stabilizes the voltage required to etch the first layer using a current density of 15 mA/cm² to the voltage level recorded in subsequent layers. The origin of this effect is not well understood, but is believed to be due to dopant surface segregation, which alters the resistivity of the surface layer. Electropolishing several hundred nanometers of the polished surface removes this inhomogeneity. The quality of a typical microcavity fabricated using 10 periods in each mirror layer is illustrated in FIG. 10. The porosities for current densities of 15 and 40 mA/cm² determined from gravimetric measurements on a roughed surface are 45% and 71.9%, respectively. These values are very similar to the porosity values of 43% and 83% obtained for current densities of 15 and 40 mA/cm², respectively, on polished wafer surfaces. Yet the effect on the pore diameter is striking, as indicated by the SEM images of two exemplary microcavity structures produced after surface roughening, shown in FIGS. 11A-B. Large pore diameters, 70-80 nm, are evident in both the low (15 mA/cm², FIG. 11A) and high (40 mA/cm², FIG. 11B) porosity structures. However, there is a larger preponderance of smaller diameter pores evident in the 15 mA/cm² structure (FIG. 11A); hence, there is a considerably smaller average pore diameter (40 nm) in the 15 mA/cm² structure compared to the average pore diameter (72 nm) of the 40 mA/cm² structure (FIG. 11B). On a nonroughened surface, a pore diameter of ˜29 nm was found using a current density of 40 mA/cm². Pore diameters exceeding 100 nm are readily fabricated in nonglycerol-containing formulations.

TABLE 8
Microcavity without electropolished top layer
(smooth surface) (average of 2 runs).

| Current | Voltage | Voltage | Voltage | Voltage |
|---|---|---|---|---|
| Density | First | Second | Third | Fourth |
| mA/cm² | Layer | Layer | Layer | Layer |
| 15 | 3.82 | 1.95 | 1.94 | 2.00 |
| 40 | 4.13 | 3.90 | 3.96 | 3.99 |

TABLE 9
Microcavity with electropolished top layer
(rough surface) (average of 2 runs).

| Current | Voltage | Voltage | Voltage | Voltage |
|---|---|---|---|---|
| Density | First | Second | Third | Fourth |
| mA/cm² | Layer | Layer | Layer | Layer |
| 100 | 10.52 | — | — | — |
| 15 | 1.86 | 1.87 | 1.81 | 1.87 |
| 40 | 3.87 | 3.82 | 3.81 | 3.74 |

### Example 7

### Post-Etch Treatments

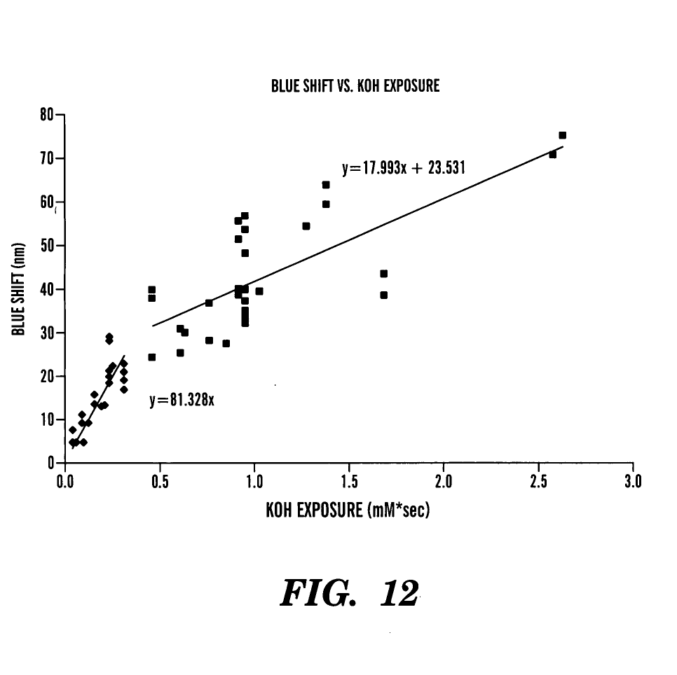

The effect of utilizing a potassium hydroxide (KOH) solution to modify pore morphology of hydride terminated porous silicon is demonstrated in the SEM images of microcavities produced using etchant #17 shown in FIGS. 5A-D. Other basic substances can be used. Examples of solvents systems tried successfully are listed in Table 10. See Examples 10-13 and FIG. 12, which illustrates the effects of KOH exposure on a p+ microcavity. The Fabry-Perot dip in reflection is monitored as a function of KOH exposure. Porous silicon is etched by the KOH. As material is eroded, the porosity increases causing a blue shift in the Fabry-Perot reflection dip. Hence, the magnitude of the blue shift provides an indication of etch rate. The KOH process is described in more detail in, for example, DeLouise & Miller, “Optimization of Mesoporous Silicon Microcavities for Proteomic Sensing,” Mat. Res. Soc. Symp. Proc. 782:A5.3.1 (2004); DeLouise & Miller, “Trends in Porous Silicon Biomedical Devices—Tuning Microstructure and Performance Trade-offs in Optical Biosensors,” Proc. SPIE 5357:111-125 (2004), each of which is hereby incorporated by reference in its entirety. Any nucleophilic substance, for example those listed in Table 10, will induce the same effect.

TABLE 10
Compounds to modify the morphology of
hydride terminated porous silicon.

| KOH | 100 μM-1 M |
|---|---|
| NaOH | 100 μM-1 M |
| NH₄OH | 0.001-30% solution |
| Pyridine | 0.1-100% |
| Formamide | 0.1-100% |
| Dimethylformamide | 0.1-100% |
| Diethylamine | 0.1-100% |
| Dimethylacetamide | 0.1-100% |

### Example 8

### Lower HF Concentrations

HF concentration is a control factor of pore size. For a given current density bigger pores are produced when the HF concentration is lowered. Bigger pores are formed when the current density approaches the electropolishing limit. Raising the HF concentration increases the current density at which electropolishing occurs.

A 20% ethanol, 7.5% HF solution yielded a structure with a 50 nm average pore diameter at 60 mA/cm². A 20% ethanol, 10% HF solution yielded a structure with a 20 nm average pore diameter at 60 mA/cm². The electropolishing limit was exceeded at 60 mA/cm² with a formulation of 20% ethanol, 5% HF, so pore diameter could not be measured. A preferred formulation would use 5-7.5% HF in water containing a surfactant to lower the surface tension.

### Example 9

### Organics/Additives

The presence of organics in the etch solution help to lower surface tension-they are not needed if surfactants are used. And while both solvents and surfactants can be used to lower the surface tension, their effect on pore morphology is different. Etchant formulas containing certain organic solvents and large molecular weight surfactants can yield by-product in the electrochemical etch process, especially at high current densities, that may leave behind a surface film on the porous silicon scaffold. This behavior is akin to the formation of surface passivation layers in gas phase etch processing of semiconductors for integrated circuit fabrication. These surface films effectively passivate side walls from further etching, enabling patterning of anisotropic features with high aspect ratios. This feature can be advantageously used to alter the surface properties and reactivity of the porous silicon films. For example, the internal surfaces of porous silicon films etched using Etchant #27 (15% HF, 85% water, 0.1 gm pluronic F108 (a high molecular weight surfactant)) are coated with an organic layer that provides protection against KOH and leaves the pore channels hydrophilic right out of the etch bath. A nonionic surfactant series that varies systematically in hydrolipid balance (HLB), surface tension and molecular weight, such as the Pluronic series (e.g., F108, F38, P105, L101, and L31), provides a means to tailor pore morphology and surface passivation.

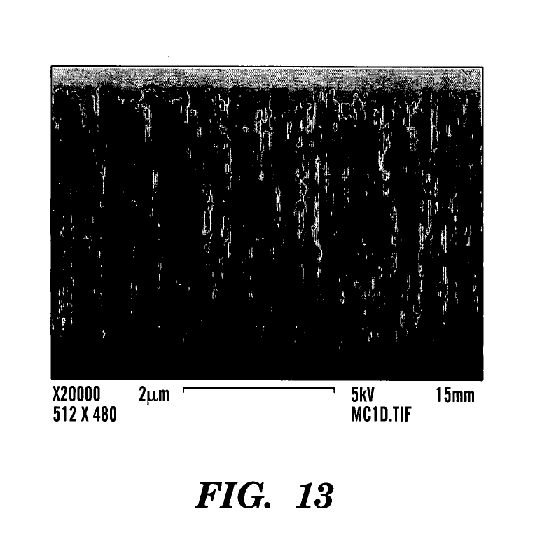

A microcavity produced from n+ silicon etched using etchant #17 is shown in FIG. 13. Each mirror contains 10 periods of high (71.9%) and low (45.0%) porosity produced using current densities of 40 and 15 mA/cm², respectively.

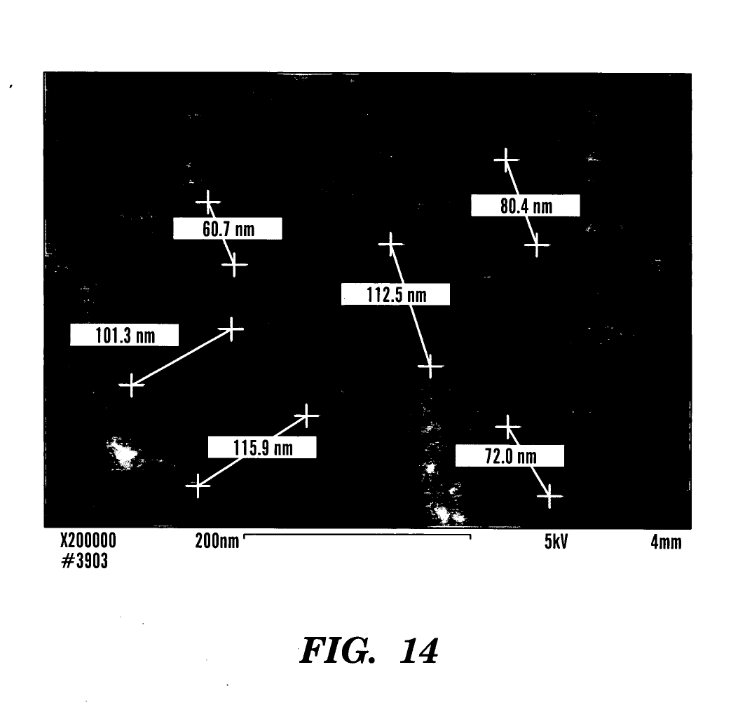

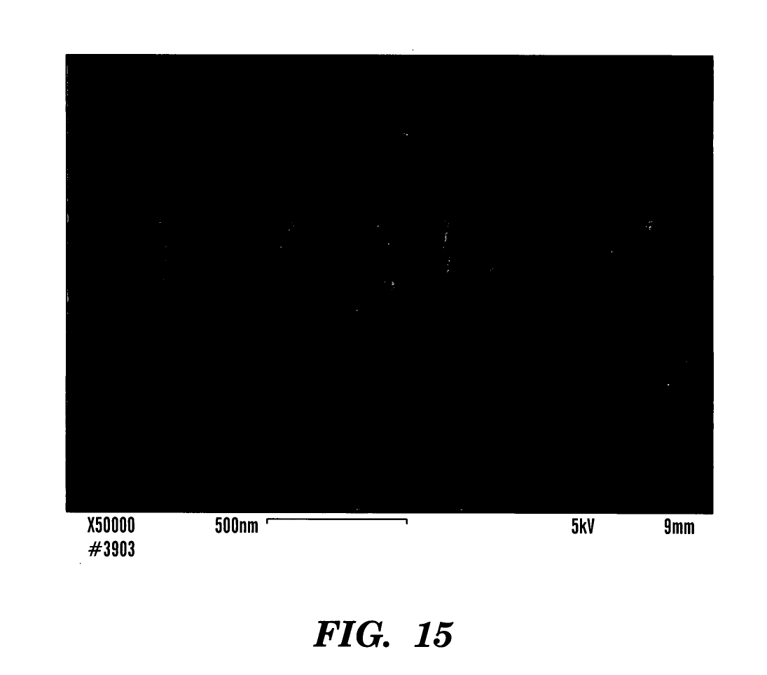

A microcavity produced from n+ silicon etched using etchant #27 at 60 mA/cm² is shown in FIGS. 14 (top view) and 15 (side view).

### Example 10

### Microcavity Fabrication

Mesoporous silicon microcavities were prepared from highly doped (boron), p+<100> silicon wafers with a resistively of 0.01 Ω-cm. Devices were electrochemically etched at room temperature in a standard Teflon etch cell (POROUS SILICON (Z. C. Feng & R. Tsu eds., 1994); Vinegoni et al., “Porous Silicon Microcavities,” in 2 SILICON BASED MATERIALS AND DEVICES 124-188 (Hari Singh Nalwa ed., 2001); Chan et al., “Identification of Gram Negative Bacteria Using Nanoscale Silicon Microcavities,” J. Am. Chem. Soc. 123:11797-11798 (2001); Chan et al., “Nanoscale Silicon Microcavity Optical Sensors for Biological Applications,” Mat. Res. Soc. Symp. Proc. 638:F10.4.1-10.4.6 (2001), which are hereby incorporated by reference in their entirety) using an electrolyte solution containing ethanol (70%) and 48% hydrofluoric acid (30%) yielding a total HF concentration of 14.4%. Multilayer microcavity structures were produced using Labview™ to alternate between high and low current densities for fixed times to produce a 1/4λ dielectric mirror stack. The number of periods of high and low porosity in each mirror stack varied between 5 and 13 depending upon the experiment as discussed in the text. Porosity was determined from gravimetric measurements made on single layer structures and etch rates were determined from SEM micrographs. Typical etch parameters used to produce the mesoporous microcavity structures investigated here are listed in Table 11. Simulations, using the Bruggeman approximation (Bruggeman, “Berechnung Verschiedener Physikalischer Konstanten von Heterogenen Substanzen,” Ann. Phys. 24:636-679 (1935), which is hereby incorporated by reference in its entirety), were used to estimate the thickness for each mirror layer and to analyze changes in the microcavity optical response as the index of refraction of fluids filled in the pores changed.

TABLE 11
Mesoporous Silicon Etch Rate vs. Current Density

| Current Density (mA/cm2) | Room Temperature Etch Rate (nm/sec) |
|---|---|
| 10 | 14 |
| 20 | 18 |
| 35 | 24 |
| 70 | 37 |

During etching the electrolyte was mildly mixed using a manual pipe pump. High Q-factor (Δλ/λ) microcavity structures (DeLouise & Miller, “Optimization of Mesoporous Silicon Microcavities for Proteomic Sensing,” Mat. Res. Soc. Symp. Proc. 2003 Fall Meeting, A5.3 (2004), which is hereby incorporated by reference in its entirety) with nearly identical resonance frequencies were reproducibly achieved using this method. Table 12 lists the peak resonances for six mesoporous λ/2 microcavity structures etched sequentially and designed to operate at 800 nm. The data are illustrative of the process control in fabricating mesoporous structures. After etching, the microcavity samples were removed from the etch cell, rinsed with ethanol, then water, and dried under a stream of N₂ gas.

TABLE 12
Reproductibility of λ/2 Microcavity Fabrication

| Sample # | Resonance Peak |
|---|---|
| 1 | 807.3 |
| 2 | 804.4 |
| 3 | 802.3 |
| 4 | 807.7 |
| 5 | 803.9 |
| 6 | 812.6 |
| AVE | 806.4 |
| STDEV | 3.7 |

### Example 11

### Microcavity Post Etch Treatments

KOH Modification

A dilute KOH solution made from a 7.7 mM KOH stock solution in water was employed to modify the intrinsic 3D microstructure of as-etched microcavity devices. Dilutions of 1:15 (0.5 mM) or 1:5 (1.5 mM) were made using 95% ethanol to aid pore infiltration. After KOH exposure, samples were rinsed in ethanol, then water, and dried under a stream of N₂ gas.

Thermal Oxidation

Microcavities were thermally oxidized to enhance photoluminescence, to impart greater stability in biological solutions and to create hydrophilic pore channels. Dry thermal oxidation was conducted using a three zone Lindberg tube furnace at 900° C. Samples were slowly shuttled into the center zone where they were annealed for 3 minutes. The entire oxidization cycle took about 16 minutes to complete.

Glutathione-S-Transferase Enzyme Activity Assay

Glutathione-S-Transferases are a family of multifunctional enzymes found in all biological systems. They are involved in the metabolism of a broad variety of chemical substances foreign to the body such as toxic carcinogens and insecticides (Ortiz-Salmerón et al., “Thermodynamic Analysis of the Binding of Glutathione to Glutathione S-Transferase Over a Range of Temperatures,” Europ. J. Biochem. 268(15):4307 (2001), which is hereby incorporated by reference in its entirety). Glutathione-S-transferases are dimeric (25 kDa/monomer) cystolic proteins that catalyze the nucleophilic attack of the thiol group (—SH) of glutathione (GSH) to the electrophilic center of the foreign substrate (Hornby et al., “Equilibrium Folding of Dimeric Class Mu Glutathione Transferases Involves a Stable Monomeric Intermediate,” Biochem. 39(40):12336-12344 (2000), which is hereby incorporated by reference in its entirety). Standard tissue assays have been developed to probe for GST activity based on the conjugation reaction between GSH and 1-chloro 2,4-dinitrobenzene (CDNB) (Habig et al., “Glutathione S-Transferases. The First Enzymatic Step in Mercapturic Acid Formation,” J. Biol. Chem. 249(22):7130-7139 (1974), which is hereby incorporated by reference in its entirety). The product of this reaction is monitored spectrophotometrically by measuring absorbance at 340 nm. This assay has been adapted to probe the effects of KOH exposure on microstructure of mesoporous microcavities as described in Examples 12-13.

Materials

GST (G6511 from equine liver 40 U specific activity), CDNB (C6396) and reduced GSH (G6529) were all were purchased from Sigma and used without further purification. All solutions were made fresh each day prior to use. Biological solutions were mixed using PBE buffer containing 100 mM potassium phosphate monobasic buffer with 1.0 mM EDTA at pH 6.5. Stock solutions of 20 mM GSH and 2 mg/ml GST were prepared in PBE and a stock solution of 100 mM CDNB was prepared in ethanol.

Solution Enzyme Reaction

Solution phase enzyme reactions were conducted prior to the immobilized solid phase reactions on microcavity chips to validate the experimental protocols and gain familiarity with enzyme kinetics. Absorbance versus time measurements were made by introducing 25 μl of GST solution (0.01-1.0 mg/ml) to a reaction tube containing (0.25-2.5 mM) GSH and 2.5 mM CDNB. Solution reactions were conducted with a total solution volume of either 75 μl or 600 μl, the former being used to more closely parallel the solid phase microcavity reactions described in Examples 12-13. Absorbance versus time was typically monitored for up to 5-10 minutes and could be quantitatively related to concentration using the molar excitation coefficient for the conjugation product, ε=9600 (μM-cm)-1. Enzyme activity was determined from the linear portion of the absorbance change with time (<3 min). Specific activity was normalized to the number of milligrams of GST utilized and found to be in good agreement with the vendor specification. Enzyme efficiency was best achieved utilizing low enzyme (<10 nM) with millimolar substrate concentrations.

Solid Phase Microcavity Enzyme Reaction

Solid phase enzyme reactions were carried out by derivatizing the microcavity chip with covalently bonded GST. The three microcavity chips referred to in Example 13 were electrochemically etched according to an equivalent procedure. Two were subsequently exposed to 1.5 mM KOH for 2 and 10 minutes, respectively. All three microcavity devices were oxidized and then derivatized with an acidified 2% aqueous glycidyl epoxy silane solution (VWR AA-30504) containing methanol for 15 minutes. The devices were rinsed with methanol, then water, dried under a stream of N₂, and baked at 100° C. for 15 minutes. The microcavity chips were next exposed to 40 μl of 5 mg/ml (˜100 nM) GST for 1 hour, after which the residual GST solution was pipetted off the surface before washing with buffer. Prior to conducting the solid phase immobilized enzyme reaction, the microcavity chip was soaked in buffer for ≧30 minutes to allow nonspecifically bound GST to desorb from the pores.

The enzyme reaction was conducted by pipetting 50 μl of ligand stock solution containing 2 mM GSH and 2 mM CDNB onto the device surface. The conjugation reaction was allowed to proceed for 5 minutes, after which 40 μl of solution was recovered from the chip surface, diluted with 560 μl PBE, and the absorbance at 340 nm recorded. Residual ligand stock solution was washed from the microcavity chip with buffer and the device allowed to soak in PBE for ≧10 minutes before running another enzyme reaction. Absorbance measurements were recorded for 5 independent chip reactions using fresh ligand stock solution and the average absorbance value reported. The linearity of the immobilized enzyme activity extends far beyond 5 minutes (DeLouise & Miller, “Enzyme Immobilization in Porous Silicon Biochip—Quantitative Analysis of the Kinetic Parameters for Glutathione-S-transferases,” Anal. Chem. 77(7): 1950-1956 (2005), which is hereby incorporated by reference in its entirety). As such, it was concluded that the magnitude of absorbance at 340 nm is proportional to the amount of functional immobilized enzyme.

Microcavity Optical Characterization

Optical characteristics were checked before and after all microcavity fabrication and surface derivatization steps by both white light reflection and photoluminescence using an Ocean Optics HR2000 system. Photoluminescence was stimulated using a fiber optic coupled 25 mW diode pumped laser at 532 nm. Prior to inserting the microcavity into the optical reader the device was dried under a stream of N₂. Optical measurements to determine the impact of GST immobilization were delayed until after conducting the GSH-CDNB conjugation reaction to preserve enzyme activity (DeLouise & Miller, “Enzyme Immobilization in Porous Silicon Biochip—Quantitative Analysis of the Kinetic Parameters for Glutathione-S-transferases,” Anal. Chem. 77(7):1950-1956 (2005), which is hereby incorporated by reference in its entirety).

### Example 12

### Mesoporous Microcavities for Biosensing Applications

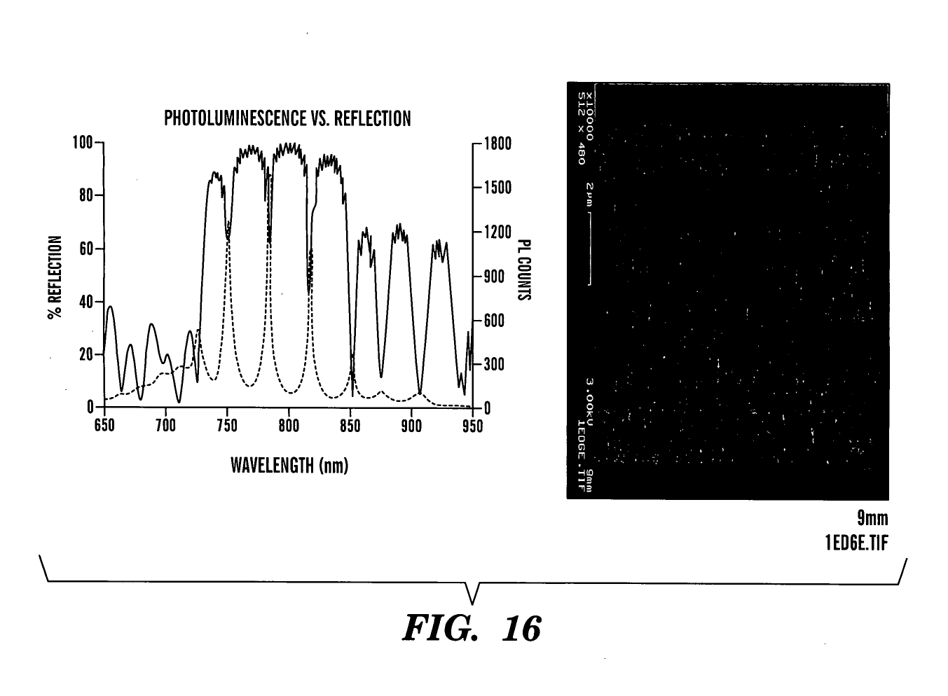

The biosensor development efforts discussed in Example 10 focus mainly around p+ mesoporous silicon resonant microcavity devices because of the convenience of etching, the greater control over porosity with current density and the resulting high interface quality compared to n-doped material. Microcavity devices are often preferred over interferometric single layer and mirror structures (Anderson et al., “Sensitivity of the Optical Properties of Porous Silicon Layers to the Refractive Index of Liquid in the Pores,” Phys. Stat. Sol. (a) 197(2):528-533 (2003); Lin et al., “A Porous Silicon-based Optical Interferometric Biosensor,” Science 278:840-843 (1997); Collins et al., “Determining Protein Size Using an Electrochemically Machined Pore Gradient in Silicon,” Adv. Func. Mat. 12:187-191 (2002), which are hereby incorporated by reference in their entirety) because they can be designed to exhibit characteristic resonance peaks in the optical response from which changes in the optical path length (ηd) induced by a molecular binding event can be unambiguously monitored. Mesoporous microcavities also offer the option to measure the sensor response in reflection or photoluminescence (PL). The resonant characteristic of the microcavity device reinforces sensor response yielding narrow line widths such that 0.5-1 nm shifts are reliably resolved. A SEM image of the cross-section of a typical microcavity device and the optical response in both reflection and photoluminescence are illustrated in FIG. 16. It is clear that complementary information can be obtained from the sensor by monitoring shifts in either the PL peaks or the reflection dips.

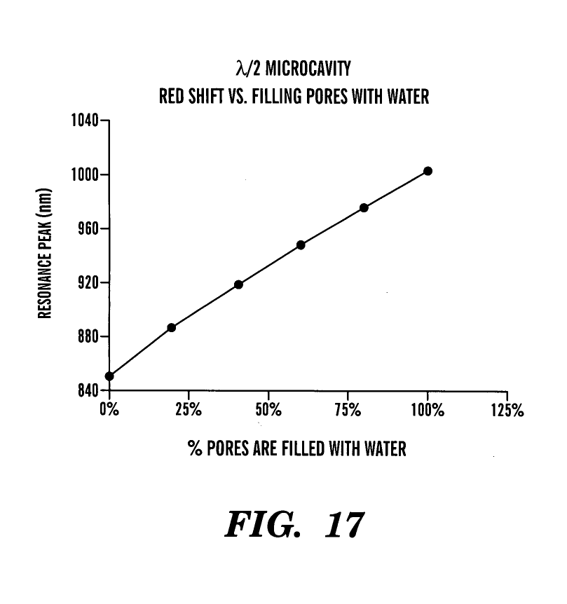

An advantage to monitoring shifts in the resonant peaks as the primary sensor response is that the magnitude of the shift is a linear function of % pore filling. A computer simulation using the Bruggeman effective medium approximation (Bruggeman, “Berechnung Verschiedener Physikalischer Konstanten von Heterogenen Substanzen,” Ann. Phys. 24:636-679 (1935), which is hereby incorporated by reference in its entirety) was conducted to investigate the effect of filling the pores with water (η=1.33) on the reflectivity spectrum of a λ/2 microcavity. Results show that as the optical thickness increases the resonant peak of a microcavity undergoes a red shift. FIG. 17 illustrates that the magnitude of the red shift is nearly linear over 150 nm, at which point the pores are filled 100% with water. Additional information can be obtained by monitoring the microcavity sensor response in the form of changes in % reflectivity and/or PL intensity. However, these changes are considerably more difficult to interpret.

Another advantage of mesoporous silicon is the high surface area (>100 m²/cm³). In addition to being able to immobilize a high concentration of probe in a biosensor application, mesoporous devices are anticipated to offer an inherent sensitivity advantage in responding to subtle alterations in porosity induced by monolayer surface modifications.

Despite the advantages of mesoporous devices discussed, there are limitations. Most notable is pore diameter. The pore diameter of a typical device ranging between 20-30 nm may restrict pore infiltration and slow diffusion of large biomolecules (>30-50 kDa). Pore diameter is believed to be linked to the root cause of an observed high level (˜50%) of sensor false negatives in preliminary efforts to develop a proteomic sensor prototype to detect the enteropathogenic and enterohemorrhagic strains of E. coli. The influence of surface energy on pore infiltration is also a concern. A decrease in the wetting characteristic of microcavity devices following surface derivatization with large proteins has been observed. This phenomenon is being investigated more thoroughly; however, preliminary observations suggest that hydrophobic interactions in addition to pore diameter play a significant role in pore infiltration.

Therefore, in attempting to develop versatile mesoporous microcavity devices for biosensor applications it is desirable to exploit available design parameters and to develop fabrication options. Example 13 discusses key design parameters including oxidation, current dependent porosity, the number of mirror periods, and post-etch KOH processing, to fabricate microcavities tuned to operate in the visible spectrum where the photoluminescence intensity is maximum.

### Example 13

### Tuning Mesoporous Microcavity for Optimum Operation Oxidation

Oxidation of mesoporous devices is a useful step in the design of microcavity biosensors. First, as discussed in Example 12, oxidizing the mesoporous silicon devices aids in creating hydrophilic surfaces to facilitate pore infiltration and subsequent surface derivatization chemistry. Second, the oxide helps to stabilize the sensor against premature corrosion in biological solutions containing high levels of salt. As-etched hydride-terminated mesoporous silicon will dissolve completely in a matter of hours while soaking in typical buffer (PBS and HEPES) solutions and even sterile solutions containing only biological levels of sodium chloride. This observation is consistent with previous reports of high porosity mesoporous silicon degradation in biological fluids (Canham et al., “Derivatized Porous Silicon Mirrors: Implantable Optical Components with Slow Resorbability,” Phys. Stat. Sol. (a) 182:521 (2000); Anderson et al., “Dissolution of Different Forms of Partially Porous Silicon Wafers Under Simulated Physiological Conditions,” Phys. Stat. Sol. (a) 197(2):331-335 (2003); Canham et al., “Derivatized Mesoporous Silicon With Dramatically Improved Stability in Simulated Human Blood Plasma,” Adv. Mat. 11:1505 (1999); Buriak & Allen, “Lewis Acid Mediated Functionalization of Porous Silicon with Substituted Alkenes and Alkynes,” J. Am. Chem. Soc. 120:1339 (1998); Stewart et al., “Three Methods for Stabilization and Functionalization of Porous Silicon Surfaces via Hydrosilylation and Electrografting Reactions,” Phys. Stat. Sol. (a) 182(1): 109-115 (2000), which are hereby incorporated by reference in their entirety), suggesting that salt is particularly corrosive. Finally, oxidation is used to enhance and stabilize the photoluminescent properties of the mesoporous silicon (Vinegoni et al., “Porous Silicon Microcavities,” in 2 SILICON BASED MATERIALS AND DEVICES 124-188 (Hari Singh Nalwa ed., 2001); Becerril-Espinoza et al., “Formation of Si/SiOx Interface and Its Influence On Photoluminescence of Si Nano-crystallites,” Microelectronics J. 34(5-8):759-761 (2003); Qin & Qin, “Multiple Mechanism Model for Photoluminescence from Oxidized Porous Si,” Phys. Stat. Sol. (a) 182(1):335-339 (2000), which are hereby incorporated by reference in their entirety).

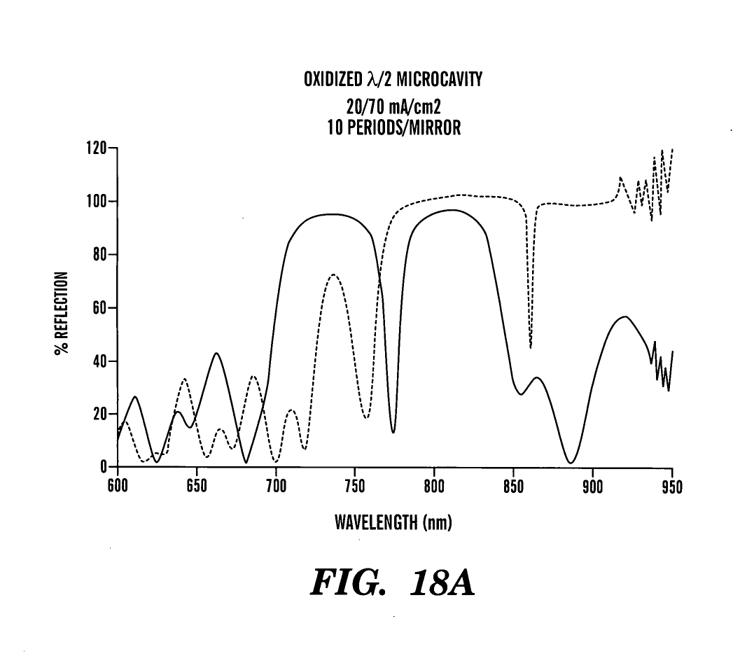

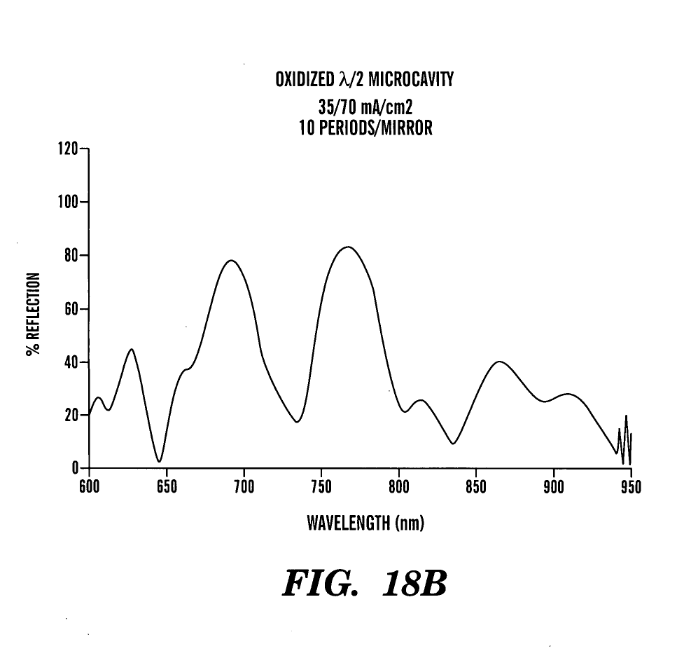

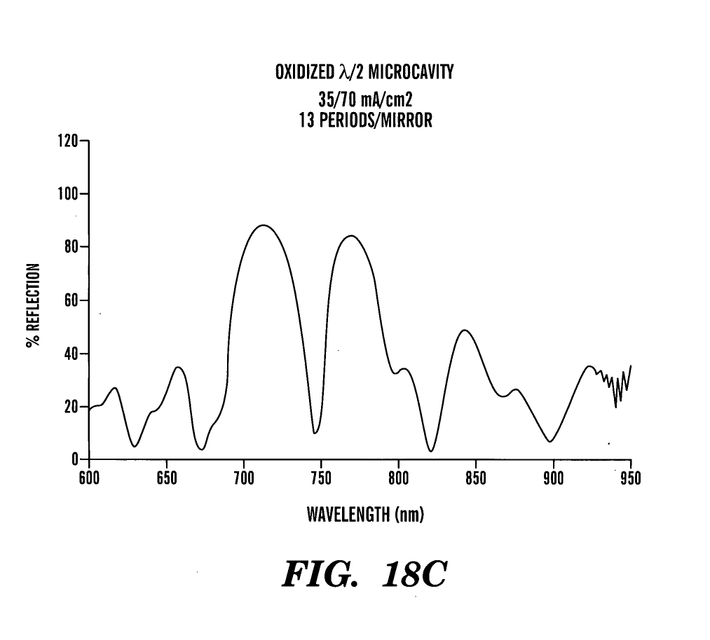

It is well known that the resonance frequencies of a microcavity device undergo a blue shift upon oxidation (Vinegoni et al., “Porous Silicon Microcavities,” in 2 SILICON BASED MATERIALS AND DEVICES 124-188 (Hari Singh Nalwa ed., 2001), which is hereby incorporated by reference in its entirety). FIG. 18A illustrates the reflection spectra of a λ/2 microcavity comprised on 10 periods per mirror, before and after oxidation. The blue shift is attributed to the fact that the index of refraction of silicon dioxide (η˜1.5) is considerably less than silicon (η˜3.0), which gives rise to a blue shift. The magnitude of the blue shift is porosity dependent. Results for λ/2 microcavities with 10 periods/mirror are summarized in Table 13 for three different porosity devices of approximate thickness. Lower porosity mirror layers fabricated using 10/35 mA/cm² exhibit a 40 nm larger blue shift than the higher porosity parts with mirror layers fabricated using 35/70 mA/cm². The larger blue shift evidenced in lower porosity parts is attributed to the larger amount of porous silicon material available for oxidation. Consequently, the blue shift must be accounted for in designing microcavities tuned to operate in a specific spectral range.

TABLE 13
Oxidation Induced Optical Blue Shift vs. Porosity

| | | Approx. | Average | |
|---|---|---|---|---|
| Current Density | | Thickness | Oxide Shift | |
| mA/cm² | Porosity (%) | (um) | (nm) | Stdev |
| 10/35 | 62/71 | 6.2 | −116.8 | 7.4 |
| 20/70 | 66/84 | 5.7 | −91.0 | 3.6 |
| 35/70 | 71/84 | 5.8 | −83.6 | 4.0 |

In addition to the optical blue shift, oxidation also causes a slight reduction in % reflection and microcavity quality as measured by the Q factor (Q=Δλ/λ). The magnitude of the degradation again depends on the porosity difference between mirror layers. FIG. 18B illustrates the greater reduction in cavity Q-factor for an oxidized 10 periods/mirror λ/2 microcavity comprised of higher porosity layers fabricated using 35/70 mA/cm². This behavior is attributed to the fact that as the porosity difference between mirror layers becomes less, so does the physical and optical differentiation of the interface which is a key factor in determining cavity quality.

Number of Mirror Periods

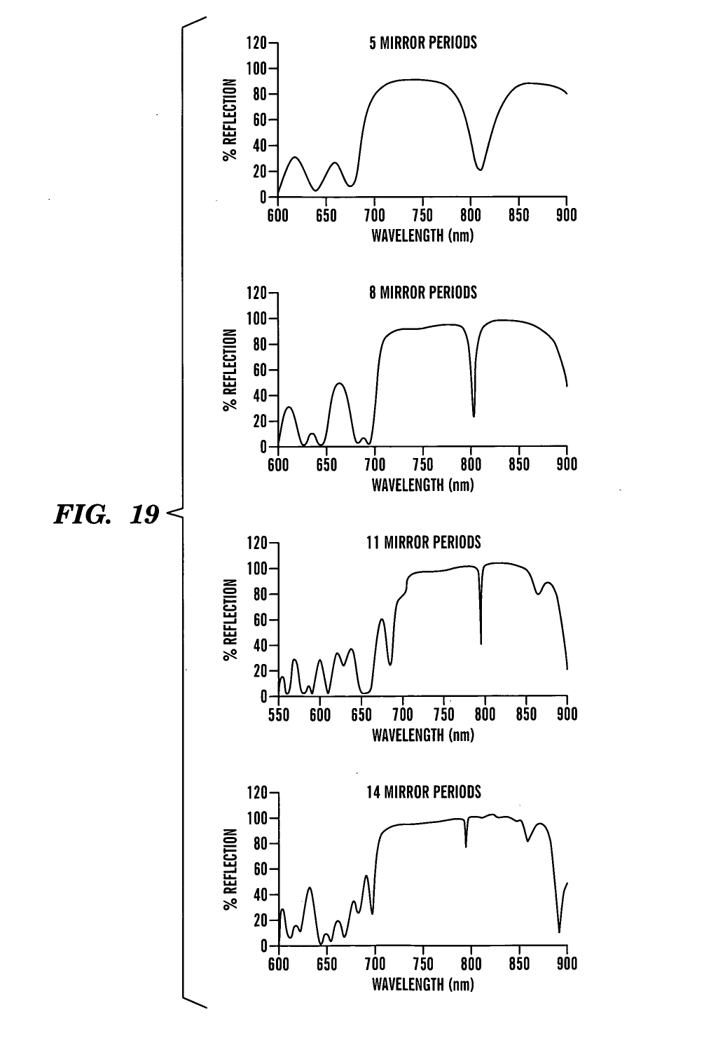

To counter the deleterious effect of oxidation, the number of mirror periods can be increased. FIG. 18C illustrates the improvement gained in the higher porosity part after oxidation simply by increasing the number of periods to 13 in each mirror. The dramatic effect of increasing the number of periods per mirror on microcavity quality for as-etched parts is illustrated in FIG. 19. Tables 14 and 15 summarize the Q-factor data for these and a higher porosity device. The results clearly show that when the porosity difference between mirror layers is less, more mirror layers are required to attain a high Q factor. Table 14. Q Factor vs. Mirror Periods for 66/84% Porosity

TABLE 14
Q Factor vs. Mirror Periods for 66/84% Porosity

| 20/70 mA/cm2 | | | |
|---|---|---|---|
| # Mirror Periods | Full Width | Lambda | Q Factor |
| 5 | 28 | 809 | 29 |
| 8 | 5.6 | 803 | 143 |
| 11 | 1.7 | 796 | 468 |
| 14 | 1.3 | 795 | 611 |

TABLE 15
Q Factor vs. Mirror Periods for 71/84% Porosity

| 35/70 mA/cm2 | | | |
|---|---|---|---|
| # Mirror Periods | Full Width | Lambda | Q Factor |
| 10 | 14 | 792 | 88 |
| 13 | 3.8 | 797 | 213 |

Pore Diameter Modification

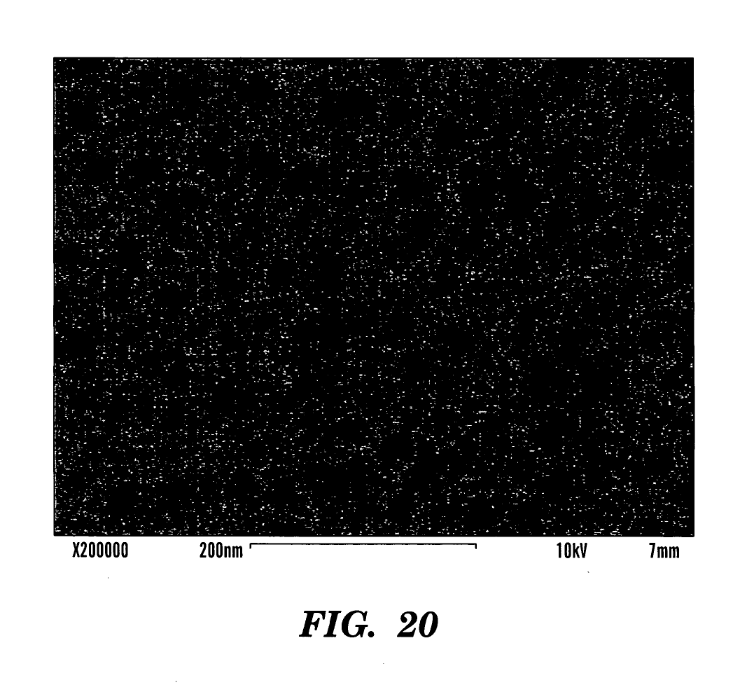

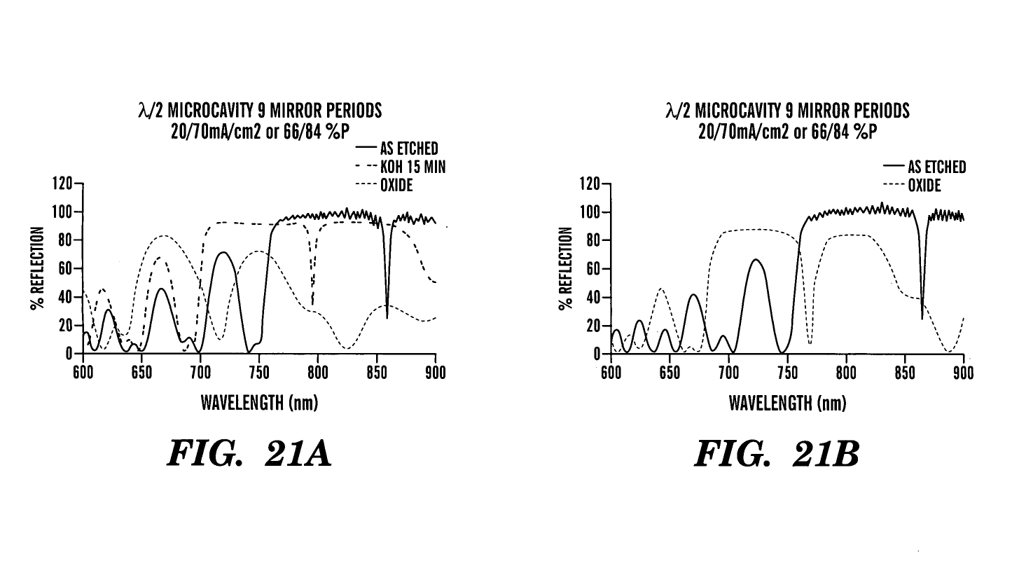

A clear shortcoming of mesoporous silicon for biosensor applications is the smaller than desired pore diameter. In etching p+ silicon, increasing the current density is more effective at increasing porosity than pore diameter. A SEM view of a typical microcavity surface, shown in FIG. 20, reveals a pore diameter in the range of ˜20-30 nm. Interpore spacing appears to range between ˜40-50 nm. This is sufficient for many applications but difficulties with pore infiltration of large biomolecules (40-50 kDa) has been experienced. To enhance pore infiltration, a KOH post-etch modification process has been developed. Strong base is typically used to etch porous silicon in gravimetric analysis measurements (Vinegoni et al., “Porous Silicon Microcavities,” in 2 SILICON BASED MATERIALS AND DEVICES 124-188 (Hari Singh Nalwa ed., 2001), which is hereby incorporated by reference in its entirety). This technique has been adapted by lowering the concentration of the KOH to the millimolar range to sufficiently slow the etch rate to systematically increase porosity and pore diameter. A similar procedure using a much higher KOH concentration has been used to fabricate macropores from n-type Si <100> mesoporous silicon (Tinsley-Bown et al., “Tuning the Pore Size and Surface Chemistry of Porous Silicon for Immunoassays,” Phys. Stat. Sol. (a) 182(1):547-553 (2000), which is hereby incorporated by reference in its entirety). However, 0.1M KOH has been found to be too corrosive, causing complete dissolution of the p+ microcavity in seconds. FIG. 21 A illustrates the effect on the reflection spectra of a microcavity exposed to 1.5 mM KOH in aqueous-ethanol for 15 minutes. The KOH exposure induced a 63 nm blue shift with minimal impact on cavity quality as evidenced by the retention of high reflectivity and only minimal impact on Q-factor (DeLouise & Miller, “Optimization of Mesoporous Silicon Microcavities for Proteomic Sensing,” Mat. Res. Soc. Symp. Proc. 2003 Fall Meeting, A5.3 (2004), which is hereby incorporated by reference in its entirety). Upon oxidation the impact of the KOH treatment was, however, more obvious when compared to the control sample, as illustrated in FIG. 21B. Incorporation of additional mirror periods would mitigate this change.

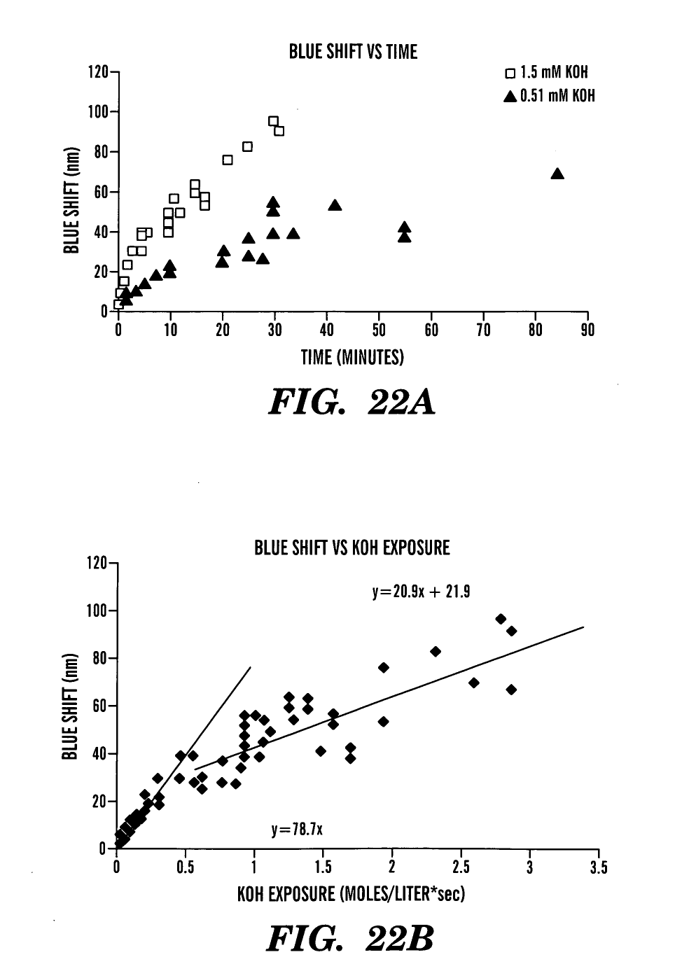

FIG. 22A illustrates the magnitude of the blue shift as a function of exposure time for two KOH concentrations. The higher the KOH concentration, the faster the rate at which porous silicon was removed. As shown in FIG. 22B, the blue shift dependence on KOH concentration can be normalized to an exposure unit defined as moles/liter*seconds. A linear least square fit to the data in FIG. 22B suggests that the KOH etch mechanism is a two step process consisting of an initial fast step (steep slope) followed by a second steady but slower etch rate process. The initial fast etch process is believed to correspond to the removal of high surface area nanostructures present within the pore channels. These nanostructures possess highly reactive exposed facets and kinks. The slower etch process represents removal of the silicon from the wall structures. Macropores in n-type material were not able to be created (Tinsley-Bown et al., “Tuning the Pore Size and Surface Chemistry of Porous Silicon for Immunoassays,” Phys. Stat. Sol. (a) 182(1):547-553 (2000), which is hereby incorporated by reference in its entirety). SEM studies indicated that even the most extreme exposures (>1 hr) only result in ˜15% increase in pore diameter (DeLouise & Miller, “Optimization of Mesoporous Silicon Microcavities for Proteomic Sensing,” Mat. Res. Soc. Symp. Proc. 2003 Fall Meeting, A5.3 (2004), which is hereby incorporated by reference in its entirety). Longer exposures resulted in catastrophic change in the cavity integrity.

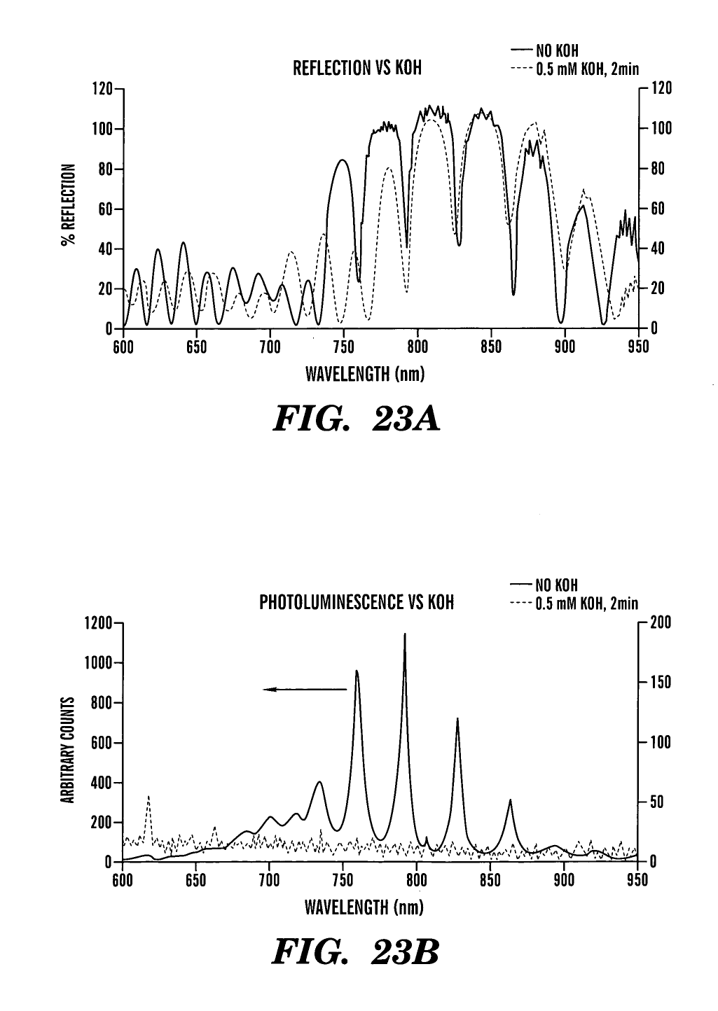

Photoluminescence data from KOH treated mesoporous microcavities also indicates that KOH etching is a two step mechanism. FIGS. 23A and 23B show photoluminescence and reflection spectra, respectively, from a microcavity exposed to 0.5 mM KOH for 2 minutes relative to a control (no KOH exposure). Both samples were thermally oxidized at 900° C. prior to these measurements. FIG. 23A indicates that photoluminescence is completely quenched from the sample treated with a relatively short KOH exposure yet the reflection spectra appear nearly identical to the control (no KOH). This result provides supporting evidence not only for the impact KOH has on modifying the nanostructures within mesoporous channels, but also lends credence to the ongoing debate over the origin of photoluminescence being integrally linked to the oxidation of nanocrystalline structures (Becerril-Espinoza et al., “Formation of Si/SiOx Interface and Its Influence On Photoluminescence of Si Nano-crystallites,” Microelectronics J. 34(5-8):759-761 (2003); Qin & Qin, “Multiple Mechanism Model for Photoluminescence from Oxidized Porous Si,” Phys. Stat. Sol. (a) 182(1):335-339 (2000), which are hereby incorporated by reference in their entirety).

GST Chip Reactions

To further assess the effect of KOH treatment on porosity and pore diameter, a comparative study of the GST enzyme conjugation reaction was conducted on three λ/2 microcavity chips fabricated with 10 periods per mirror using 20/70 mA/cm². One sample was exposed to 1.5 mM KOH for 2 minutes (0.18 M-sec, fast etch regime, −18 nm blue shift), and a second sample for 10 minutes (0.92 M-sec, slower etch regime, −45 nm blue shift). A third chip served as a control (no KOH). Samples were oxidized and derivatized with epoxy silane prior to GST immobilization. Details of the GST chip reaction and a comparison of the solid state kinetics to solution phase activity are reported in Example 11.

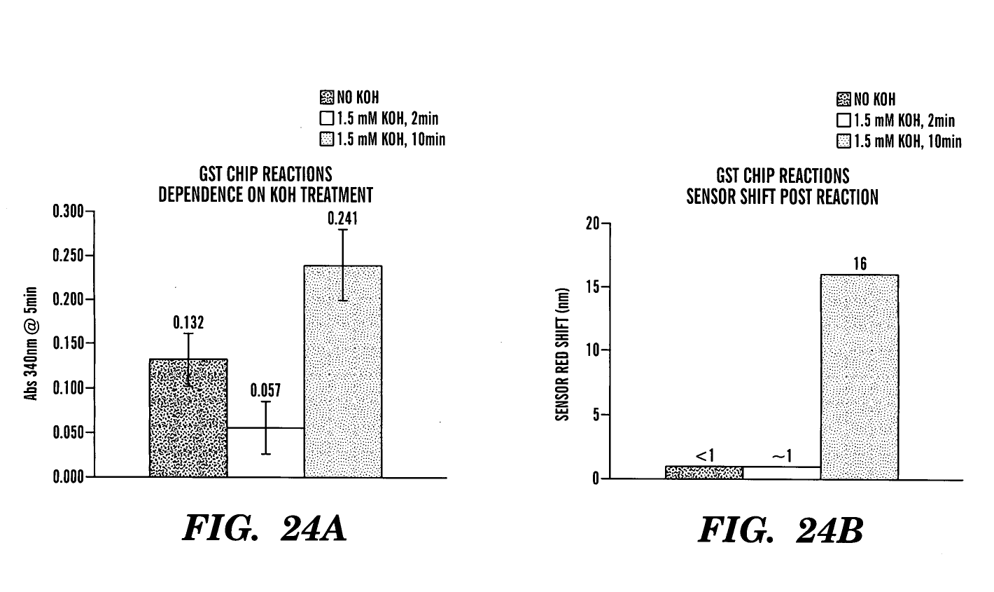

The pore diameter in microcavities, where one of the layers in the periodic mirror stack is etched at 20 mA/cm², is insufficient to allow facile penetration of the GST enzyme (50 kDa) (DeLouise & Miller, “Optimization of Mesoporous Silicon Microcavities for Proteomic Sensing,” Mat. Res. Soc. Symp. Proc. 2003 Fall Meeting, A5.3 (2004), which is hereby incorporated by reference in its entirety). After immobilizing 50 μl of GST solution (5 mg/ml, ˜5 nmol) onto the three microcavities, the GSH-CDNB conjugation reaction was allowed to proceed for 5 minutes. FIG. 24A indicates the relative amount of conjugation product from the three devices. It is believed that the absorbance intensity is proportional to the relative amount of functional GST present in the device and that the determining factors for the amount of immobilized GST are the available surface area and pore penetration. The data in FIG. 24A suggests that nearly equivalent or just slightly less functional GST is immobilized on the microcavity chip treated with KOH for 2 minutes relative to the control (no KOH). However, it is certain that nearly two times more functional GST is immobilized in the chip treated with KOH for 10 minutes.

Further insight into these results was gained from the optical response of microcavity chips measured after completing the GSH-CDNB reaction. The optical shift data are illustrated in FIG. 24B. The apparent lack of a sensor shift for the control device (no KOH) and the microcavity treated with KOH for 2 minutes suggests that little or no GST penetrated the porous 3D microstructure. Hence, the conjugation product formed on this device results from GST immobilized on the chip surface only. In comparison, the optical response for the microcavity exposed to KOH for 10 minutes yielded a substantial +16 nm red shift. The red shift indicates the binding of GST within the 3D porous microstructure of the device. Thus, in addition to surface bound enzyme, conjugation product is also formed from functional GST immobilized within the pores. This is consistent with the nearly 2-fold larger absorbance intensity. This result supports the notion that longer exposure to KOH is effective at increasing the pore diameter in p+ mesoporous silicon.

Summary

The advantages and design considerations of utilizing p+ mesoporous silicon microcavities in optical biosensing applications has been discussed. This is an attractive technology because the fabrication methods are inexpensive and sufficiently flexible such that devices can be reproducibly made. The device fabrication parameters can be sufficiently controlled to enable the tailoring of the device microstructure and quality (Q-factor) to overcome some of the limitations of pore infiltration. Specifically it has been established that a dilute KOH solution is an effective means to systematically modify the pore structure in mesoporous devices to enable the ingress of larger biomolecules (˜50 kDa). A consequence of this treatment, however, is that the high surface area nanostructures responsible for giving rise to efficient photoluminescence are readily removed. As such, KOH treated sensors can be operated in reflection mode only.

Although preferred embodiments have been depicted and described in detail herein, it will be apparent to those skilled in the relevant art that various modifications, additions, substitutions, and the like can be made without departing from the spirit of the invention and these are therefore considered to be within the scope of the invention as defined in the claims which follow.

What is claimed:

1. An etch solution comprising about 0-50% ethanol, about 0-25% dimethyl formamide, about 0-30% glycerol, about 5-20% hydrofluoric acid, about 0-90% water, and about 0-1% surfactant.

2. The etch solution according to claim 1 comprising about 0-25% ethanol, about 0-25% dimethyl formamide, about 0-30% glycerol, about 7.5-20% hydrofluoric acid, about 0-85% water, and about 0-1% surfactant.

3. The etch solution according to claim 2 comprising about 25% ethanol, about 10% dimethyl formamide, about 20% hydrofluoric acid, and about 45% water.

4. The etch solution according to claim 2 comprising about 10% ethanol, about 10% dimethyl formamide, about 20% hydrofluoric acid, and about 60% water.

5. The etch solution according to claim 2, comprising about 25% ethanol, about 25% dimethyl formamide, about 30% glycerol, and about 20% hydrofluoric acid.

6. The etch solution according to claim 2, comprising about 10% ethanol, about 25% dimethyl formamide, about 5-30% glycerol, about 20% hydrofluoric acid, and about 15-40% water.

7. The etch solution according to claim 6, comprising about 10% ethanol, about 25% dimethyl formamide, about 5-12% glycerol, about 20% hydrofluoric acid, and about 33-40% water.

8. The etch solution according to claim 6, comprising about 10% ethanol, about 25% dimethyl formamide, about 30% glycerol, about 20% hydrofluoric acid, and about 15% water.

9. The etch solution according to claim 1, comprising about 0-35% ethanol, about 0-10% dimethyl formamide, about 0-30% glycerol, about 10-20% hydrofluoric acid, about 0-1% surfactant, and about 4-90% water.

10. The etch solution according to claim 9, comprising about 35% ethanol, about 30% glycerol, about 15% hydrofluoric acid, about 0.1% surfactant, and about 19% water, wherein the surfactant comprises pluronic F108.

11. The etch solution according to claim 1, wherein the surfactant is selected from the group of nonionic surfactants, cationic surfactants, and anionic surfactants.

12. The etch solution according to claim 11, wherein the surfactant is selected from the group of alkylphenol ethoxylate, alcohol ethoxylates, Rheodol series sorbitan esters, ethylene oxide/polyethylene oxide block polymers, pluronic F108, pluronic F108, pluronic F38, pluronic P105, pluronic L101, pluronic L31, Dowfax series polymers, Triton series alkylpolyglucosides, quaternary ammonium compounds, and alkyl, aryl, and ethyl sulfates and phosphates.

13. The etch solution according to claim 1, further comprising an oxidizing agent.

14. The etch solution according to claim 13, wherein the oxidizing agent is selected from the group of chromium trioxide, ammonium persulfate, osmium tetroxide, and potassium permanganate.

15. The etch solution according to claim 1, comprising about 15% hydrofluoric acid, about 85% water, and about 0.1% surfactant.

16. A method of preparing a porous semiconductor structure comprising:
providing a semiconductor material, and
etching the semiconductor material in the etch solution of claim 1 under conditions effective to produce a porous semiconductor structure.

17. The method according to claim 16, said method further comprising treating the semiconductor material with a post electrochemical etch solution after said etching the semiconductor material, wherein the post electrochemical solution is suitable to cause pore opening.

18. The method according to claim 17, wherein the post electrochemical etch solution comprises about 100 μM-1 M KOH, about 100 μM-1 M NaOH, about 0.001-1% NH₄OH, about 1-100% pyridine, about 1-100% formamide, about 1-100% dimethylformamide, about 1-100% diethylamine, or about 1-100% dimethylacetamide.

19. The method according to claim 16, wherein the etch solution comprises about 25% ethanol, about 10% dimethyl formamide, about 20% hydrofluoric acid, and about 45% water.

20. The method according to claim 16, wherein the etch solution comprises about 10% ethanol, about 10% dimethyl formamide, about 20% hydrofluoric acid, and about 60% water.

21. The method according to claim 16, wherein the etch solution comprises about 25% ethanol, about 25% dimethyl formamide, about 30% glycerol, and about 20% hydrofluoric acid.

22. The method according to claim 16, wherein the etch solution comprises about 10% ethanol, about 25% dimethyl formamide, about 5-30% glycerol, about 20% hydrofluoric acid, and about 15-40% water.

23. The method according to claim 16, wherein the etch solution comprises about 35% ethanol, about 30% glycerol, about 15% hydrofluoric acid, about 0.1% surfactant, and about 19% water, wherein the surfactant comprises pluronic F108.

24. The method according to claim 16, wherein the etch solution comprises about 15% hydrofluoric acid, about 85% water, and about 0.1% pluronic F108.

25. A porous semiconductor structure produced according to the method of claim 16 wherein the porous semiconductor structure has an average pore size of about 3 to about 40 nm and an average porosity of about 34 to about 49%.

26. A porous semiconductor structure produced according to the method of claim 17 wherein the porous semiconductor structure has an average pore size of about 39 nm and an average porosity greater than 71%.

27. A porous semiconductor structure produced according to the method of claim 19, wherein the porous semiconductor structure has an average pore size of at least about 19 nm and an average porosity of at least about 44%.

28. A porous semiconductor structure produced according to the method of claim 20 wherein the porous semiconductor structure has an average pore size of at least about 19 nm and an average porosity of less than about 40%.

29. A porous semiconductor structure produced according to the method of claim 21 wherein the porous semiconductor structure has an average pore size of less than about 12 nm and an average porosity of at least about 49%.

30. A porous semiconductor structure produced according to the method of claim 22 wherein the porous semiconductor structure has an average pore size of less than about 8 nm and an average porosity of less than about 42%.

31. A porous semiconductor structure produced according to the method of claim 23 wherein the porous semiconductor structure has an average pore size of at least about 29 nm and an average porosity of at least about 40%.

32. A porous semiconductor structure produced according to the method of claim 24 wherein the porous semiconductor structure has an average pore size of at least about 82 nm and an average porosity of at least about 79%.
